(19) United States
(12) Patent Application Publication
(10) Pub. No.: US 2022/0165799 A1
(43) Pub. Date: May 26, 2022

(54) SOLID-STATE IMAGING DEVICE AND IMAGING APPARATUS

(71) Applicant: SONY SEMICONDUCTOR SOLUTIONS CORPORATION, KANAGAWA (JP)

(72) Inventor: OSAMU ENOKI, KANAGAWA (JP)

(21) Appl. No.: 17/440,921

(22) PCT Filed: Feb. 20, 2020
(86) PCT No.: PCT/JP2020/006727

§ 371 Date: Sep. 20, 2021

(30) Foreign Application Priority Data
Mar. 29, 2019 (JP) 2019-065439

(51) Int. Cl. H01L 27/30; H01L 51/44; H04N 9/04; H04N 5/369

(52) U.S. Cl. CPC H01L 27/307; H04N 5/369; H04N 9/0455; H01L 51/44

(57) ABSTRACT

A solid-state imaging device and an imaging apparatus capable of realizing further miniaturization of an imaging apparatus and further improvement of light use efficiency are to be provided. The present technology provides a solid-state imaging device that includes a plurality of pixels arranged one- or two-dimensionally, in which each pixel includes at least a light receiving unit, and the light receiving unit included in at least some of the plurality of pixels have circularly polarized dichroism. The present technology also provides an imaging apparatus that includes at least: the solid-state imaging device; and a signal processing unit that generates an image capturing only specific circularly polarized light, on the basis of a signal obtained from at least one of the pixels of the solid-state imaging device.

### TECHNICAL FIELD

The present technology relates to a solid-state imaging device and an imaging apparatus.

### BACKGROUND ART

Circularly polarized dichroism is a phenomenon in which absorbance varies for right and left circularly polarized light, and is caused by optical activity (chirality) of molecules. Circularly polarized dichroic spectrum information is expected to be applied to analysis of a higher-order structure of a physiologically active substance, object identification, foreign object detection, and the like.

Various suggestions have been made on techniques for capturing circularly polarized dichroic images. For example, Patent Document 1 suggests a technique for alternately emitting right circularly polarized light and left circularly polarized light to a sample, capturing an image formed by the transmitted light that has passed through the sample, and outputting a circularly dichroic image from a difference between a right circularly polarized image and a left circularly polarized image. Also, Patent Document 2 suggests an imaging apparatus characteristically including: a pupil-dividing polarizing means that divides light from the target object passing through an exit pupil of an imaging optical system into a pair of light fluxes (right circularly polarized light and left circularly polarized light, for example) having different centers of gravity and different polarization characteristics; and an imaging device in which pixels that selectively receive the respective light fluxes are two-dimensionally arranged.

### CITATION LIST

### Patent Documents

Patent Document 1: Japanese Patent Application Laid-Open No. 2012-021885
Patent Document 2: Japanese Patent Application Laid-Open No. 2008-015157

### SUMMARY OF THE INVENTION

### Problems to be Solved by the Invention

However, with the techniques suggested in Patent Documents 1 and 2, there is a possibility that the size of an imaging apparatus cannot be further reduced, and light use efficiency cannot be further increased. Therefore, a principal object of the present technology is to provide a solid-state imaging device and an imaging apparatus that are capable of realizing further miniaturization of an imaging apparatus and further improvement of light use efficiency.

### Solutions to Problems

The present inventors have conducted intensive studies to solve the above problems, and have completed the present technology.

Specifically, the present technology provides a solid-state imaging device that includes a plurality of pixels arranged one- or two-dimensionally, in which each pixel includes at least a light receiving unit, and the light receiving unit included in at least some of the plurality of pixels have circularly polarized dichroism.

In this example, the light receiving unit of each of the pixels may include a filter unit, the filter unit may include at least an optical filter, and the optical filter included in the at least one of the pixels may contain a material having circularly polarized dichroism.

Also, the light receiving unit of each of the pixels may include one photoelectric conversion unit, and the filter unit may be disposed on the photoelectric conversion unit.

Alternatively, the light receiving unit of each of the pixels may include a plurality of photoelectric conversion units, the plurality of photoelectric conversion units may be stacked in a vertical direction, and the filter unit may be disposed between the plurality of photoelectric conversion units.

Further, the filter unit may include a color filter, and the color filter and the optical filter may be stacked.

The colors of the color filters of the respective pixels may be arranged so as to form a Bayer array in which each adjacent pixel has a different color, and the optical filters have different sensitivities to circularly polarized light between adjacent sets of repetitive units in the Bayer array.

The colors of the color filters of the respective pixels may be arranged so as to form a Bayer array in which each adjacent set of 2×2 pixels has a different color, and the optical filters have different sensitivities to circularly polarized light between adjacent sets of repetitive units in the Bayer array.

The colors of the color filters of the respective pixels may be arranged so as to form a Bayer array in which each adjacent pixel has a different color, and the optical filter in at least one of the pixels forming a set of repetitive units in the Bayer array has a different sensitivity to circularly polarized light from the other pixels forming the set of repetitive units.

The colors of the color filters of the respective pixels may be arranged so as to form a Bayer array in which each adjacent sets of 2×2 pixels has a different color, and the optical filter in at least one of the pixels forming a set of repetitive units in the Bayer array has a different sensitivity to circularly polarized light from the other pixels forming the set of repetitive units.

Further, the light receiving unit of each of the pixels may include a filter unit, the filter unit may include at least a color filter, and the color filter included in the at least one of the pixels may contain a material having circularly polarized dichroism.

The colors of the color filters of the respective pixels may be arranged so as to form a Bayer array in which each adjacent pixel has a different color, and the color filters have different sensitivities to circularly polarized light between adjacent sets of repetitive units in the Bayer array.

The colors of the color filters of the respective pixels may be arranged so as to form a Bayer array in which each adjacent sets of 2×2 pixels has a different color, and the color filters have different sensitivities to circularly polarized light between adjacent sets of repetitive units in the Bayer array.

The colors of the color filters of the respective pixels may be arranged so as to form a Bayer array in which each adjacent pixel has a different color, and the color filter in at least one of the pixels forming a set of repetitive units in the Bayer array has a different sensitivity to circularly polarized light from the other pixels forming the set of repetitive units.

The colors of the color filters of the respective pixels may be arranged so as to form a Bayer array in which each adjacent sets of 2×2 pixels has a different color, and the color filter in at least one of the pixels forming a set of repetitive units in the Bayer array has a different sensitivity to circularly polarized light from the other pixels forming the set of repetitive units.

Alternatively, the light receiving unit of each of the pixels may include one or more photoelectric conversion units, at least one photoelectric conversion unit of the one or more photoelectric conversion units may include an organic photoelectric conversion element, the organic photoelectric conversion element may include a pair of electrodes and a photoelectric conversion layer provided between the electrodes, and the photoelectric conversion layer of the organic photoelectric conversion element included in the at least one of the pixels may contain a material having circularly polarized dichroism.

Of the one or more photoelectric conversion units in the at least one of the pixels, at least one photoelectric conversion unit may include at least a first organic photoelectric conversion element and a second organic photoelectric conversion element, and the first organic photoelectric conversion element and the second organic photoelectric conversion element may have different sensitivities to circularly polarized light.

Further, the light receiving unit of each of the pixels may include: a first photoelectric conversion unit that photoelectrically converts light of a first color component; a second photoelectric conversion unit that photoelectrically converts light of a second color component; and a third photoelectric conversion unit that photoelectrically converts light of a third color component, one or more of the first, second, and third photoelectric conversion units may each include an organic photoelectric conversion element, and the photoelectric conversion layer of the organic photoelectric conversion element included in the at least one of the pixels may contain a material having circularly polarized dichroism.

Of the first, second, and third photoelectric conversion units in the at least one of the pixels, at least one photoelectric conversion unit may include at least a first organic photoelectric conversion element and a second organic photoelectric conversion element, and the first organic photoelectric conversion element and the second organic photoelectric conversion element may have different sensitivities to circularly polarized light.

Alternatively, the light receiving unit of each of the pixels may include, in this order: a first photoelectric conversion unit that photoelectrically converts light of a first color component; a filter unit; and a second photoelectric conversion unit that photoelectrically converts light of a second color component that has passed through the filter unit, one or more of the first and second photoelectric conversion units may each include an organic photoelectric conversion element, and the photoelectric conversion layer of the organic photoelectric conversion element included in the at least one of the pixels may contain a material having circularly polarized dichroism.

Of the first and second photoelectric conversion units in the at least one of the pixels, at least one photoelectric conversion unit may include at least a first organic photoelectric conversion element and a second organic photoelectric conversion element, and the first organic photoelectric conversion element and the second organic photoelectric conversion element may have different sensitivities to circularly polarized light.

Further, the light receiving unit of each of the pixels may include a filter unit and a photoelectric conversion unit disposed in this order, the photoelectric conversion unit may include at least one panchromatic photosensitive organic photoelectric conversion film, and the panchromatic photosensitive organic photoelectric conversion film included in the at least one of the pixels may contain a material having circularly polarized dichroism.

The present technology further provides an imaging apparatus that includes at least: the solid-state imaging device described above; and a signal processing unit that generates an image capturing only specific circularly polarized light, on the basis of a signal obtained from the at least one of the pixels of the solid-state imaging device.

The signal processing unit may further generate an image not depending on the type of circularly polarized light, on the basis of a signal obtained from a pixel other than the at least one of the pixels.

The signal processing unit may interpolates information in each pixel, on the basis of information between adjacent pixels.

### BRIEF DESCRIPTION OF DRAWINGS

FIG. 1 is an example configuration of a solid-state imaging device of a first embodiment according to the present technology.

FIG. 2 is example layouts in cases where an optical filter is used as a filter unit of the first embodiment according to the present technology.

FIG. 3 is an example layout in a case where an optical filter and a color filter are stacked as a filter unit of the first embodiment according to the present technology.

FIG. 4 is an example layout in a case where an optical filter and a color filter are stacked as a filter unit of the first embodiment according to the present technology.

FIG. 5 is example layouts in cases where a color filter is used as a filter unit of the first embodiment according to the present technology.

FIG. 6 is an example configuration of a solid-state imaging device of a second embodiment according to the present technology.

FIG. 7 is an example configuration of a solid-state imaging device of a third embodiment according to the present technology.

FIG. 8 is an example configuration of a solid-state imaging device of a fourth embodiment according to the present technology.

FIG. 9 is an example configuration of a solid-state imaging device of a fifth embodiment according to the present technology.

FIG. 10 is an example configuration of a solid-state imaging device of a sixth embodiment according to the present technology.

FIG. 11 is a schematic configuration diagram showing an example of a solid-state imaging device that can be applied to the present technology.

FIG. 12 is an example configuration of an imaging apparatus according to a seventh embodiment of the present technology.

FIG. 13 is an example of image processing by the imaging apparatus of the seventh embodiment according to the present technology.

FIG. 14 is an example of image processing by the imaging apparatus of the seventh embodiment according to the present technology.

FIG. 15 is a diagram showing examples of use of a solid-state imaging device to which the present technology is applied.

FIG. 16 is a diagram schematically showing an example configuration of an endoscopic surgery system.

FIG. 17 is a block diagram showing an example of the functional configurations of a camera head and a CCU.

FIG. 18 is a block diagram schematically showing an example configuration of a vehicle control system.

FIG. 19 is an explanatory diagram showing an example of installation positions of external information detectors and imaging units.

### MODES FOR CARRYING OUT THE INVENTION

The following is a description of preferred embodiments for carrying out the present technology. Note that the embodiments described below are typical embodiments of the present technology, and the scope of the present technology is not limited to these embodiments.

Note that explanation of the present technology will be made in the following order.

1. Outline of the present technology

2. First embodiment (an example of a solid-state imaging device containing a circularly polarized dichroic material in a filter unit)

3. Second embodiment (a modification of the first embodiment)

4. Third embodiment (an example of a solid-state imaging device containing a circularly polarized dichroic material in a photoelectric conversion unit)

5. Fourth embodiment (a modification of the third embodiment)

6. Fifth embodiment (an example of a solid-state imaging device containing a circularly polarized dichroic material in a panchromatic photosensitive organic photoelectric conversion film)

7. Sixth embodiment (a modification of the fifth embodiment)

8. Seventh embodiment (an imaging apparatus)

9. Examples of use of solid-state imaging devices to which the present technology is applied

10. Example application to an endoscopic surgery system

11. Example applications to mobile structures

### 1. Outline of the Present Technology

First, an outline of the present technology is described.

The present technology relates to a solid-state imaging device and an imaging apparatus.

Techniques for capturing a circularly polarized dichroic image include a technique for alternately emitting right circularly polarized light and left circularly polarized light to a sample, capturing an image formed by the transmitted light that has passed through the sample, and outputting a circularly polarized dichroic image from a difference between a right circularly polarized image and a left circularly polarized image. By this technique, it is necessary to use a light source whose circularly polarized light is controlled, and it might be difficult to reduce the size of an imaging apparatus in some cases.

Meanwhile, a contact-type image sensor called a contact image sensor (CIS) has been attracting attention as a technique for reducing the size of an imaging apparatus. There is a technique for capturing a circularly polarized dichroic image by providing an imaging apparatus with a circularly polarizing filter. However, to mount a circularly polarizing filter on a CIS, a very thin wavelength plate (about 15 μm in the case of crystal, for example) needs to be used, which makes practical use of the technique difficult. Also, even when a circularly polarizing filter that can be mounted on a CIS is used, reflection loss occurs, and therefore, light use efficiency is not very high in some cases.

As a result of various studies, the present inventors have found that it is possible to solve the above problems by imparting circularly polarized dichroism to the light receiving unit included in at least some of the plurality of pixels in a solid-state imaging device. Note that, in this specification, a “light receiving unit” includes an on-chip lens, an optical filter, a color filter, a photodiode, and an organic photoelectric conversion element, for example.

That is, the present technology can provide a solid-state imaging device and an imaging apparatus that are capable of further reducing the size of the imaging apparatus and further increasing light use efficiency, by imparting circularly polarized dichroism to the light receiving unit included in at least some of the plurality of pixels in the solid-state imaging device.

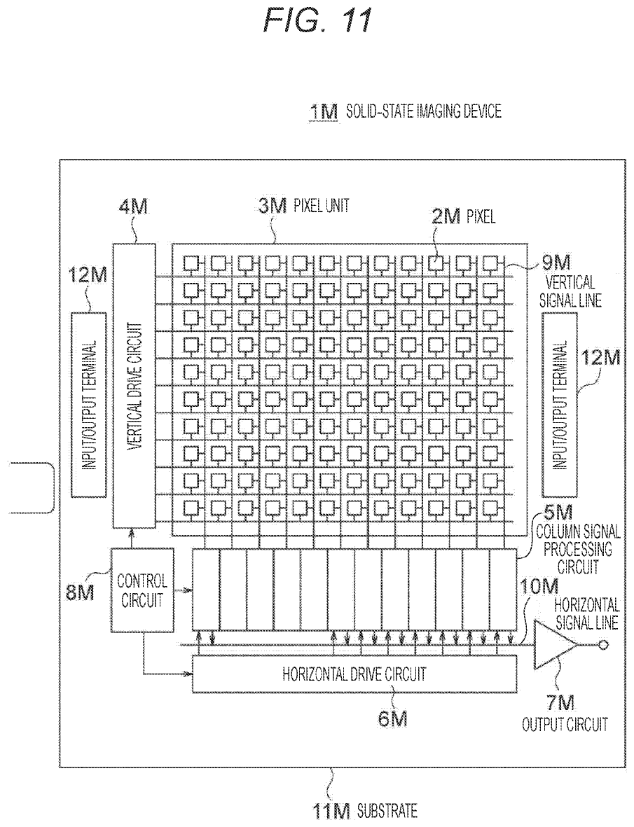

Next, an example schematic configuration of a solid-state imaging device according to the present technology applicable to each embodiment explained below is described with reference to FIG. 11.

As shown in FIG. 11, a solid-state imaging device 1M includes a pixel unit that is a pixel region (or an imaging region) 3M, and a peripheral circuit unit. In the pixel region 3M, pixels 2M including a plurality of photoelectric conversion elements are two-dimensionally arranged with regularity on a semiconductor substrate 11M such as a silicon substrate, for example. A pixel 2M includes a photoelectric conversion element such as a photodiode, for example, and a plurality of pixel transistors (so-called MOS transistors). The plurality of pixel transistors may be formed with the three transistors: a transfer transistor, a reset transistor, and an amplification transistor, for example. Alternatively, the pixel transistors may be formed with the four transistors: a selection transistor in addition to the above transistors. The equivalent circuit of a unit pixel is similar to a conventional one, and therefore, detailed explanation thereof is not made herein. The pixels 2M can also be a shared pixel structure. This shared pixel structure includes a plurality of photodiodes, a plurality of transfer transistors, a shared floating diffusion, and each of the other shared pixel transistors, for example.

The peripheral circuit unit includes a vertical drive circuit 4M, column signal processing circuits 5M, a horizontal drive circuit 6M, an output circuit 7M, and a control circuit 8M.

The control circuit 8M receives an input clock and data that designates an operation mode and the like, and also outputs data such as internal information about the solid-state imaging device. Specifically, on the basis of a vertical synchronization signal, a horizontal synchronization signal, and a master clock, the control circuit 8M generates a clock signal and a control signal that serve as the references for operations of the vertical drive circuit 4M, the column signal processing circuits 5M, the horizontal drive circuit 6M, and the like. The control circuit 8M then inputs these signals to the vertical drive circuit 4M, the column signal processing circuits 5M, the horizontal drive circuit 6M, and the like.

The vertical drive circuit 4M is formed with a shift register, for example. The vertical drive circuit 4M selects a pixel drive line, supplies a pulse for driving pixels to the selected pixel drive line, and drives the pixels on a row-by-row basis. Specifically, the vertical drive circuit 4M sequentially selects and scans the respective pixels 2M of the pixel unit 3M on a row-by-row basis in the vertical direction, and supplies pixel signals based on signal charges generated in accordance with the amounts of light received at photodiodes that are the photoelectric conversion elements of the respective pixels 2M, for example, to the column signal processing circuits 5M through vertical signal lines 9M.

The column signal processing circuits 5M are provided for the respective columns of the pixels 2M, and perform signal processing, such as denoising on a column-by-column basis, for example, on signals that are output from the pixels 2M of one row. Specifically, the column signal processing circuits 5M perform signal processing, such as CDS, signal amplification, and AD conversion, to remove fixed pattern noise unique to the pixels 2M. Horizontal select switches (not shown) are provided between and connected to the output stages of the column signal processing circuits 5M and a horizontal signal line 10M.

The horizontal drive circuit 6M is formed with a shift register, for example, sequentially selects the respective column signal processing circuits 5M by sequentially outputting horizontal scan pulses, and causes the respective column signal processing circuits 5M to output pixel signals to the horizontal signal line 10M.

The output circuit 7M performs signal processing on signals sequentially supplied from the respective column signal processing circuits 5M through the horizontal signal line 10, and outputs the processed signals. For example, the output circuit 7M might perform only buffering, or might perform black level control, column variation correction, various kinds of digital signal processing, and the like. Input/output terminals 12M exchange signals with the outside.

The following is a detailed description of preferred embodiments for carrying out the present technology. The embodiments described below are typical examples of embodiments of the present technology, and do not narrow the interpretation of the scope of the present technology.

### 2. First Embodiment (an Example of a Solid-State Imaging Device Containing a Circularly Polarized Dichroic Material in a Filter Unit)

A solid-state imaging device according to a first embodiment of the present technology is described. The solid-state imaging device of this embodiment has a configuration in which the light receiving unit of each pixel includes a filter unit, and the filter unit included in at least one of the pixels contains a material having circularly polarized dichroism (hereinafter, this material will be referred to as a “circularly polarized dichroic material”). Note that, in this specification, a “filter unit” refers to a portion including one or more optical filters and/or color filters in a solid-state imaging device.

In this embodiment, by adopting a configuration in which the filter unit of at least one pixel contains a circularly polarized dichroic material, it is possible to further reduce the size of the solid-state imaging device and increase light use efficiency, as compared with a case where a general circularly polarizing filter is used.

Furthermore, by using a circularly polarized dichroic material, it is possible to produce a filter that selectively senses only a wavelength compatible with the purpose. As it is possible to manufacture the filter simply by applying a circularly polarized dichroic material, it is easy to manufacture the filter. Further, as the circularly polarized dichroism of the filter unit is determined by the characteristics of the circularly polarized dichroic material, the step of achieving a uniform orientation is unnecessary. Furthermore, as will be described later, the circularly polarized dichroic material can be applied to each pixel, and thus, information having different sensitivities to circularly polarized light between adjacent pixels can be obtained.

(2-1. Back-Illuminated Solid-State Imaging Device)

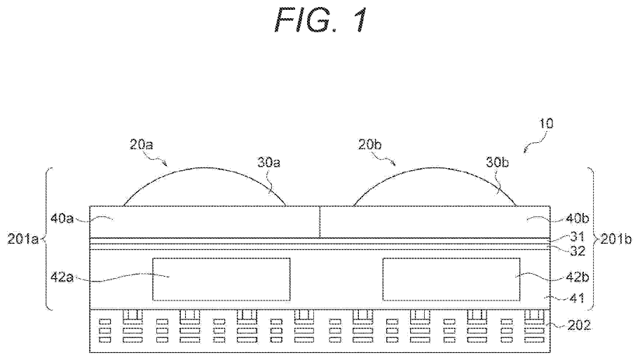

Referring now to FIG. 1, an example of a back-illuminated solid-state imaging device is described. FIG. 1 is a cross-sectional diagram schematically showing an example configuration of a back-illuminated solid-state imaging device according to this embodiment. In a back-illuminated solid-state imaging device 10 of this embodiment, each pixel 20 includes a light receiving unit 201 on a wiring layer 202. The light receiving unit 201 of each pixel includes one photoelectric conversion unit (photodiode 42), and has a structure in which a filter unit 40 is disposed above the photoelectric conversion unit 42 via a protective layer 32 and a planarizing layer 31. Further, an on-chip lens 30 is disposed on the filter unit 40. In the description below, the respective layers are explained.

[On-Chip Lens 30]

The on-chip lens 30 condenses incident light onto the photoelectric conversion unit (photodiode 42). The on-chip lens 30 is formed with a high refractive index material that has optical transparency and a refractive index higher than 1.5, for example. The high refractive index material forming the on-chip lens 30 may be an inorganic material having a high refractive index, such as SiN, for example, but it is also possible to use an organic material having a high refractive index, such as an episulfide resin, a thietane compound, or a resin thereof.

It is also possible to further increase the refractive index of the on-chip lens 30 by using a metal thietane compound as disclosed in Japanese Patent Application Laid-Open No. 2013-139449, or a polymerizable composition containing the metal thietane compound. Further, it is possible to obtain a higher refractive index material by adding an oxide or a nitride having a refractive index of about 2 to 2.5, such as TiO₂, ZrO₂, Ta₂O₅, Nb₂O₅, ZnO, or Si₃N₄, to any of these resins.

The method for forming the on-chip lens 30 is not limited to any particular method, but it is possible to form the on-chip lens 30 by performing an etchback process after forming a lens-shaped resist film on a lens material film, for example. Other than that, the on-chip lens 30 may be formed by patterning a photosensitive resin film by a photolithography technique, and then deforming the photosensitive resin film into a lens shape by a reflow process, or may be formed by deforming the photosensitive resin film.

The shape of the on-chip lens 30 is not limited to any particular shape, and various lens shapes such as a hemispherical shape and a semi-cylindrical shape can be adopted. As shown in FIG. 1, one on-chip lens 30 may be provided for each photoelectric conversion unit (photodiode 42) (or for each pixel 20). However, one on-chip lens 30 may be provided for each set of a plurality of photoelectric conversion units (photodiodes 42) (or for each set of a plurality of pixels 20).

[Filter Unit 40]

The filter unit 40 transmits incident light condensed by the on-chip lens 30. In this embodiment, the filter unit 40 included in at least some pixels 20 in the plurality of pixels 20 contains a circularly polarized dichroic material. As the circularly polarized dichroic material, a known compound having circularly polarized dichroism can be used. For example, a chiral compound having a molecular structure in which no symmetry planes exist can be used. More specifically, it is possible to use a chiral dye in which a substituent is introduced into a dye such as quinacridone, coumarin, cyanine, squarylium, dipyrromethene (BODIPY), phthalocyanine, subphthalocyanine, porphyrin, perylene, indigo, or thioindigo, to form a molecular structure having no symmetry planes, for example. Also, this material preferably has a high absorption coefficient, to prevent the film thickness of the filter unit from becoming too large. More specifically, the absorption coefficient calculated by dividing the absorbance measured with an ultraviolet-visible near-infrared spectrophotometer by the film thickness measured with a stylus-type step profiler is preferably 50,000 to 500,000 cm⁻¹.

In the filter unit 40 of this embodiment, the circularly polarized dichroic material may be included only in the portion corresponding to one pixel 20 among the pixels 20 constituting the solid-state imaging device 10, or the circularly polarized dichroic material may be included in the portion corresponding to all the pixels 20 constituting the solid-state imaging device 10.

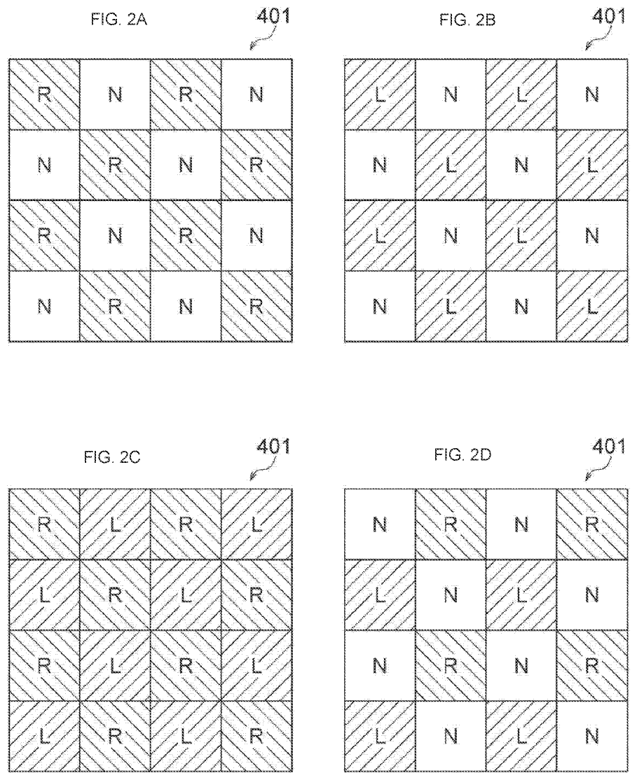

Further, the filter unit 40 may be formed only with an optical filter 401 containing a circularly polarized dichroic material in the portion corresponding to at least one of the pixels 20, may be formed with a stack of the optical filter 401 and a color filter 402, or may be formed only with a color filter 402 containing a circularly polarized dichroic material in the portion corresponding to at least one of the pixels 20. In the description below, each example configuration is explained, with reference to FIGS. 2 to 5.

FIGS. 2(a) to 2(d) show example layouts in cases where the filter unit 40 is formed only with the optical filter 401 containing a circularly polarized dichroic material in the portion corresponding to at least one of the pixels 20. In FIG. 2, one square corresponds to one pixel 20, an “R” is a portion containing a material that preferentially transmits right circularly polarized light, an “L” is a portion containing a material that preferentially transmits left circularly polarized light, and an “N” is a portion not containing any circularly polarized dichroic material.

As shown in FIGS. 2(a) and 2(b), the portions “R” or “L” containing a circularly polarized dichroic material and the portions “N” not containing any circularly polarized dichroic material may be alternately arranged for the respective pixels 20. As shown in FIG. 2(c), the portions “R” and “L” containing a circularly polarized dichroic material may be alternately arranged for the respective pixels 20. As shown in FIG. 2(d), the portions “R” and “L” containing a circularly polarized dichroic material and the portions “N” not containing any circularly polarized dichroic material may be alternately arranged for the respective pixels 20.

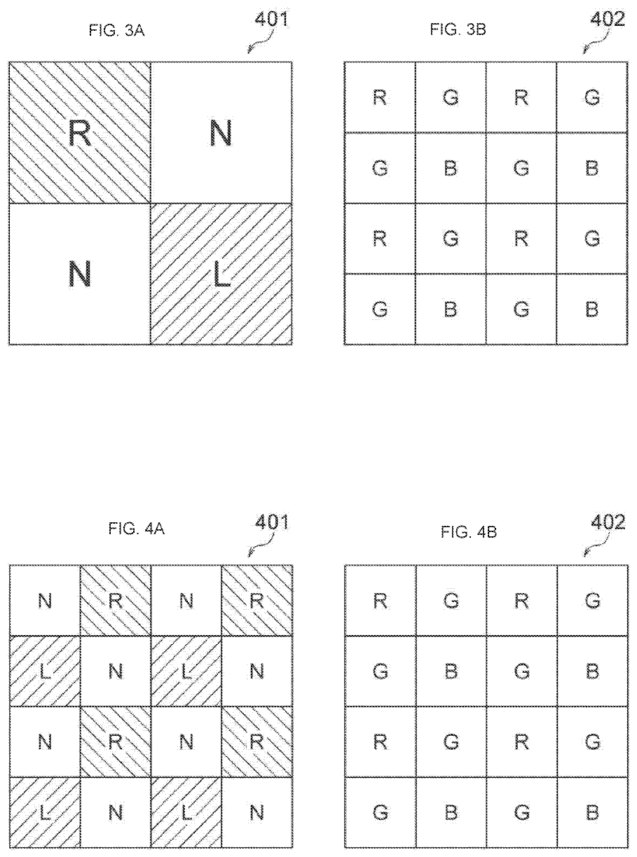

FIGS. 3 and 4 show example layouts in cases where the filter unit 40 is formed with a stack of the optical filter 401 containing a circularly polarized dichroic material in the portion corresponding to at least one of the pixels 20, and the color filter 402. In FIGS. 3(a) and 4(a), one square corresponds to 2×2 pixels 20. In FIGS. 3(b) and 4(b), an “R” is a red color filter that causes light to pass through a red wavelength band, a “G” is a green color filter that causes light to pass through a green wavelength band, and a “B” is a blue color filter that causes light to pass through a blue wavelength band.

As shown in FIGS. 3(a) and 3(b), the colors of the color filter 402 of the respective pixels may be arranged in a Bayer array in which each adjacent pixel has a different color, and the optical filter 401 may be designed so that the sensitivity to circularly polarized light varies for each set of 2×2 repetitive units in the Bayer array. Alternatively, as shown in FIGS. 4(a) and 4(b), the colors of the color filter 402 of the respective pixels may be arranged in a Bayer array in which each adjacent pixel has a different color, and the optical filter 401 may be designed so that the sensitivity to circularly polarized light in at least one pixel differs from the other pixels among the pixels constituting a set of 2×2 repetitive units in the Bayer array.

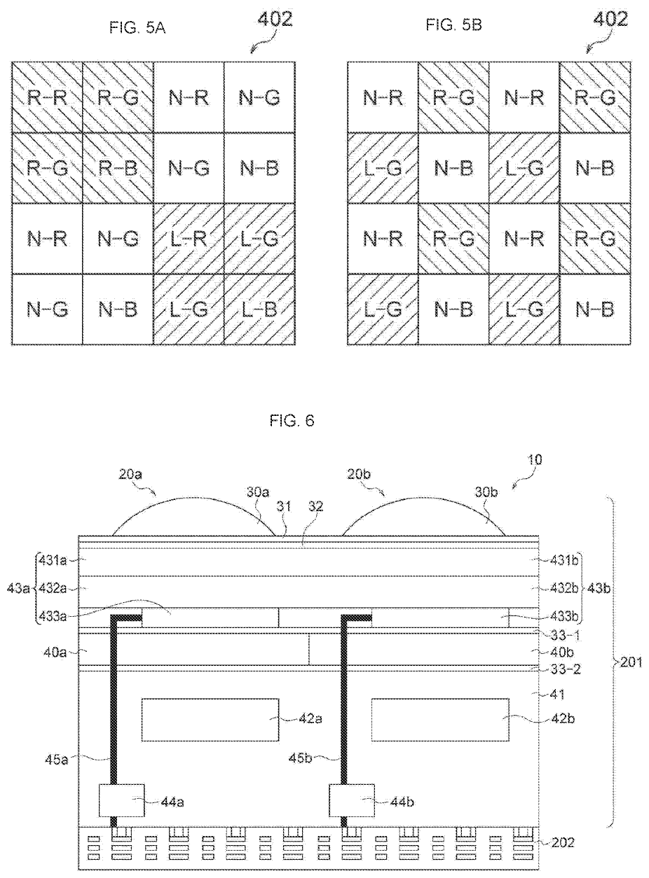

FIG. 5 shows example layouts in cases where the filter unit 40 is formed only with the color filter 402 containing a circularly polarized dichroic material in the portion corresponding to at least one of the pixels 20. In FIG. 5, one square corresponds to one pixel 20, an “R-R” is a red color filter that contains a material that preferentially transmits right circularly polarized light, and causes light to pass through a red wavelength band, an “L-R” is a red color filter that contains a material that preferentially transmits left circularly polarized light, and causes light to pass through a red wavelength band, and an “N-R” is a red color filter that does not contain any circularly polarized dichroic material and causes light to pass through a red wavelength band, for example.

As shown in FIG. 5(a), the colors of the color filter 402 of the respective pixels may be arranged in a Bayer array in which each adjacent pixel has a different color, and be designed so that the sensitivity to circularly polarized light varies for each set of 2×2 repetitive units in the Bayer array. Alternatively, as shown in FIG. 5(b), the colors of the color filter 402 of the respective pixels may be arranged in a Bayer array in which each adjacent pixel has a different color, and be designed so that the sensitivity to circularly polarized light in at least one pixel differs from the other pixels among the pixels constituting a set of 2×2 repetitive units in the Bayer array.

[Planarizing Layer 31 and Protective Layer 32]

The planarizing layer 31 and the protective layer 32 include materials having optical transparency, for example.

The material forming the planarizing layer 31 may be a resin having optical transparency, such as acrylic resin, styrene resin, or epoxy resin, for example. Meanwhile, the material forming the protective layer 32 may be an inorganic material having optical transparency, such as silicon oxide, silicon nitride, or silicon oxynitride, for example.

Note that the protective layer 32 may also serve as the planarizing layer 31.

[Photodiode 42]

The photodiode 42 is a photodiode having a p-n junction, and is formed in a semiconductor substrate (silicon substrate) 41. Light that has entered the photodiode 42 is photoelectrically converted, and is output as an electrical signal.

[Operation of the Solid-State Imaging Device 10]

In the description below, operation of the solid-state imaging device 10 of this embodiment is explained.

In FIG. 1, light that has entered the solid-state imaging device 10 is refracted and condensed by the on-chip lens 30, and passes through the filter unit 40. After that, the incident light that has passed through the filter unit 40 passes through the planarizing layer 31 and the protective layer 32, and is condensed on the photodiode 42. The light that has entered the photodiode 42 is then photoelectrically converted, and is output as an electrical signal.

In a case where the filter unit 40 has the layout shown in FIG. 2 at this stage, it is possible to obtain a monochrome circularly polarized image having different sensitivities to circularly polarized light between adjacent pixels 20.

Alternatively, in a case where the filter unit 40 has the layout shown in FIG. 3 or FIG. 5(a), it is possible to obtain a circularly polarized image in which each set of 2×2 repetitive units in the Bayer array has a different sensitivity to circularly polarized light, and each adjacent pixel 20 has a different color.

Further, in a case where the filter unit 40 has the layout shown in FIG. 4 or FIG. 5(b), it is possible to obtain a circularly polarized image in which at least one of the pixels constituting a set of 2×2 repetitive units in the Bayer array has a different sensitivity to circularly polarized light, and each adjacent pixel 20 has a different color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

Note that a case where “R” (red), “G” (green), and “B” (blue) are arranged so as to form a Bayer array as a color filter 402 in which each adjacent pixel has a different color, and a set of repetitive units in the Bayer array is formed with 2×2 pixels has been explained above. However, pixels may be arranged so as to form a Bayer array in which each set of adjacent 2×2 pixels has a different color, and a set of repetitive units in the Bayer array may be formed with 4×4 pixels.

In this case, to form the correspondence relationship shown in FIGS. 3(a) and 3(b), the colors of the color filter 402 of the respective pixels may be arranged in a Bayer array in which each set of adjacent 2×2 pixels has a different color, and the optical filter 401 may be designed so that the sensitivity to circularly polarized light varies for each set of 4×4 repetitive units in the Bayer array.

Also, to form the correspondence relationship shown in FIGS. 4(a) and 4(b), the colors of the color filter 402 of the respective pixels may be arranged in a Bayer array in which each set of adjacent 2×2 pixels has a different color, and the optical filter 401 may be designed so that the sensitivity to circularly polarized light in at least one pixel differs from the other pixels among the pixels constituting 4×4 repetitive units in the Bayer array.

Alternatively, to form the correspondence relationship shown in FIG. 5(a), the colors of the color filter 402 of the respective pixels may be arranged in a Bayer array in which each set of adjacent 2×2 pixels has a different color, and be designed so that the sensitivity to circularly polarized light varies for each set of 4×4 repetitive units in the Bayer array.

Further, to form the correspondence relationship shown in FIG. 5(b), the colors of the color filter 402 of the respective pixels may be arranged in a Bayer array in which each set of adjacent 2×2 pixels has a different color, and be designed so that the sensitivity to circularly polarized light in at least pixel differs from the other pixels among the pixels constituting 4×4 repetitive units in the Bayer array.

Furthermore, the color filter 402 is not necessarily formed with RGB filters, and complementary color filters of “Y” (yellow), “C” (cyan), and “M” (magenta) may be used. For example, a configuration in which YCMG filters are arranged in a color difference sequential system may be adopted. Alternatively, a filter that can transmit light in a broad wavelength region or all wavelength regions, such as an IR filter, a white filter, a gray filter, a clear filter, or a panchromatic filter (a filter that transmits light in the entire visible light region), may be used in combination with RGB filters.

(2-2. Front-Illuminated Solid-State Imaging Device)

The solid-state imaging device of this embodiment can be applied not only to a back-illuminated solid-state imaging device but also to a front-illuminated solid-state imaging device. An example of a front-illuminated solid-state imaging device differs from the above back-illuminated solid-state imaging device 10 only in that the wiring layer 202 formed under the semiconductor substrate 41 is formed between the color filter 40 and the semiconductor substrate 41. Other aspects may be similar to those of the back-illuminated solid-state imaging device 10 described above, and explanation of them is not made herein.

### 3. Second Embodiment (a Modification of the First Embodiment)

A solid-state imaging device according to a second embodiment of the present technology is described. The solid-state imaging device according to this embodiment is a modification of the solid-state imaging device described above in <2. First Embodiment>.

(3-1. Back-Illuminated Solid-State Imaging Device)

Referring now to FIG. 6, an example of a back-illuminated solid-state imaging device is described. FIG. 6 is a cross-sectional diagram schematically showing an example configuration of a back-illuminated solid-state imaging device according to this embodiment. In a back-illuminated solid-state imaging device 10 of this embodiment, each pixel 20 includes a light receiving unit 201 on a wiring layer 202. The light receiving unit 201 of each pixel has a structure in which a plurality of photoelectric conversion units (an organic photoelectric conversion element 43 and a photodiode 42) is stacked in a vertical direction (light incident direction), and a filter unit 40 is disposed between the plurality of photoelectric conversion units (the organic photoelectric conversion element 43 and the photodiode 42) via insulating films 33-1 and 33-2. In the description below, the respective layers are explained. Note that, in the solid-state imaging device of this embodiment, the basic configurations of the on-chip lens 30, the filter unit 40, the planarizing layer 31, the protective layer 32, and the photodiode 42 are as described above in <2. First Embodiment>, and therefore, explanation of them is not made herein.

[Organic Photoelectric Conversion Element 43]

The organic photoelectric conversion element 43 includes an upper electrode 431, a lower electrode 433, and a photoelectric conversion layer 432 provided between these electrodes. The upper electrode 431 and the lower electrode 433 may be formed with a transparent conductive film, such as an indium tin oxide film or an indium zinc oxide film, for example. Note that, although not shown in the drawing, the organic photoelectric conversion element 43 may include an electron transport layer and a hole transport layer. The organic photoelectric conversion element 43 is semi-transmissive, and part of light that has entered the organic photoelectric conversion element 43 is photoelectrically converted and is output as an electrical signal.

In one pixel 20, a wiring line 45 connected to the lower electrode 433 and a wiring line (not shown) connected to the upper electrode 431 are formed. The wiring line 45 and the wiring line connected to the upper electrode 431 can be formed with tungsten (W) plugs each having a SiO₂ or SiN insulating layer in its periphery, semiconductor layers formed by ion implantation, or the like, to prevent short-circuiting with Si, for example.

Further, an n-type region 44 for charge accumulation is formed in the semiconductor substrate 41. This n-type region 44 functions as the floating diffusion portion of the organic photoelectric conversion element 43.

[Insulating Films 33]

As the insulating films 33-1 and 33-2, a film having a negative fixed charge can be used. The film having a negative fixed charge may be a hafnium oxide film, for example. The insulating films 33-1 and 33-2 may be formed to have a three-layer structure in which a silicon oxide film, a hafnium oxide film, and a silicon oxide film are formed in this order.

[Operation of the Solid-State Imaging Device 10]

In the description below, operation of the solid-state imaging device 10 of this embodiment is explained.

In FIG. 6, light that has entered the solid-state imaging device 10 is refracted and condensed by the on-chip lens 30, passes through the planarizing layer 31 and the protective layer 32, and enters the organic photoelectric conversion element 43. After that, part of the incident light that has passed through the organic photoelectric conversion element 43 passes through the insulating film 33-1, the filter unit 40, and the insulating film 33-2, and is then condensed onto the photodiode 42. The light that has entered the organic photoelectric conversion element 43 and the photodiode 42 is then photoelectrically converted, and is output as an electrical signal.

In a case where the filter unit 40 has the layout shown in FIG. 2 at this stage, the organic photoelectric conversion element 43 can obtain an unpolarized image, and the photodiode 42 can obtain a monochrome circularly polarized image having different sensitivities to circularly polarized light between adjacent pixels 20.

Also, in a case where the filter unit 40 has the layout shown in FIG. 3 or FIG. 5(a), the organic photoelectric conversion element 43 can obtain an unpolarized image, and the photodiode 42 can obtain a circularly polarized image in which at least one of the pixels constituting 2×2 repetitive units in the Bayer array has a different sensitivity to circularly polarized light, and each adjacent pixel 20 has a different color.

Further, in a case where the filter unit 40 has the layout shown in FIG. 4 or FIG. 5(b), the organic photoelectric conversion element 43 can obtain an unpolarized image, and the photodiode 42 can obtain a circularly polarized image in which each set of 2×2 repetitive units in the Bayer array has a different sensitivity to circularly polarized light, and each adjacent pixel 20 has a different color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

As described above, in the solid-state imaging device 10 of this embodiment, information about an unpolarized image and a circularly polarized image can be obtained by one pixel 20.

Note that, although the configuration in which the organic photoelectric conversion element 43 and the photodiode 42 are stacked in a vertical direction as a plurality of photoelectric conversion units has been described above, a configuration in which only a plurality of organic photoelectric conversion elements 43 is stacked in a vertical direction, or a configuration in which only a plurality of photodiodes 42 is stacked in a longitudinal direction may be adopted, for example. In a case where only a plurality of photodiodes 42 is stacked in a vertical direction, the photodiode 42 on the front side in the light incident direction is preferably formed as a semi-transmissive thin film.

(3-2. Front-Illuminated Solid-State Imaging Device)

The solid-state imaging device of this embodiment can be applied not only to a back-illuminated solid-state imaging device but also to a front-illuminated solid-state imaging device. An example of a front-illuminated solid-state imaging device differs from the above back-illuminated solid-state imaging device 10 only in that the wiring layer 202 formed under the semiconductor substrate 41 is formed between the filter unit 40 and the semiconductor substrate 41. Other aspects may be similar to those of the back-illuminated solid-state imaging device 10 described above, and explanation of them is not made herein.

### 4. Third Embodiment (an Example of a Solid-State Imaging Device Containing a Circularly Polarized Dichroic Material in a Photoelectric Conversion Unit)

A solid-state imaging device according to a third embodiment of the present technology is described. In the solid-state imaging device of this embodiment, the light receiving unit of each pixel includes one or more photoelectric conversion units, and at least one photoelectric conversion unit of the one or more photoelectric conversion units includes an organic photoelectric conversion element. Further, the organic photoelectric conversion element includes a pair of electrodes, and a photoelectric conversion layer provided between the electrodes. The photoelectric conversion layer of the organic photoelectric conversion element included in at least one of the pixels contains a circularly polarized dichroic material.

In this embodiment, by adopting a configuration in which the photoelectric conversion unit of at least one of the pixels contains a circularly polarized dichroic material, it is possible to further reduce the size of the solid-state imaging device and increase light use efficiency, as compared with a case where a general circularly polarizing filter is used.

Furthermore, by using a circularly polarized dichroic material, it is possible to produce a photoelectric conversion element that selectively senses only a wavelength compatible with the purpose. As it is possible to manufacture the photoelectric conversion element simply by applying a circularly polarized dichroic material, it is easy to manufacture the photoelectric conversion element. Further, as the circularly polarized dichroism of the photoelectric conversion element is determined by the characteristics of the circularly polarized dichroic material, the step of achieving a uniform orientation is unnecessary. Furthermore, as will be described later, the circularly polarized dichroic material can be applied to each pixel, and thus, information having different sensitivities to circularly polarized light between adjacent pixels can be obtained.

(4-1. Back-Illuminated Solid-State Imaging Device)

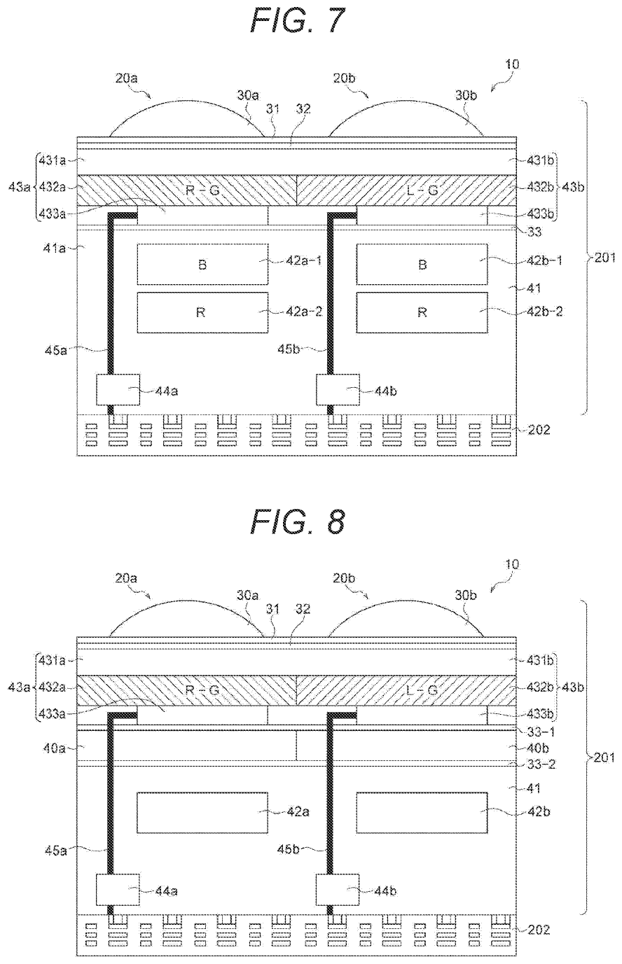

Referring now to FIG. 7, an example of a back-illuminated solid-state imaging device is described. FIG. 7 is a cross-sectional diagram schematically showing an example configuration of a back-illuminated solid-state imaging device according to this embodiment. In a back-illuminated solid-state imaging device 10 of this embodiment, each pixel 20 includes a light receiving unit 201 on a wiring layer 202. The light receiving unit 201 of each pixel has a structure including a plurality of photoelectric conversion units (an organic photoelectric conversion element 43, a first photodiode 42-1, and a second photodiode 42-2), and a filter unit 40 is disposed above the photoelectric conversion units via a protective layer 32 and a planarizing layer 31. Further, an on-chip lens 30 is disposed on the filter unit 40. In the description below, the respective layers are explained. Note that, in the solid-state imaging device of this embodiment, the basic configurations of the on-chip lens 30, the filter unit 40, the planarizing layer 31, the protective layer 32, the insulating film 33, the photodiodes 42, and the organic photoelectric conversion element 43 are as described above in <2. First Embodiment> and the like, and therefore, explanation of them is not made herein.

The solid-state imaging device 10 of this embodiment has a configuration in which each one pixel 20 includes an organic photoelectric conversion element 43 (a first photoelectric conversion unit), the first photodiode 42-1 (a second photoelectric conversion unit) having a p-n junction, and the second photodiode 42-2 (a third photoelectric conversion unit). In the example of the solid-state imaging device shown in FIG. 7, the organic photoelectric conversion element 43 (the first photoelectric conversion unit) is for the green color (G), the first photodiode 42-1 (the second photoelectric conversion unit) is for the blue color (B), and the second photodiode 42-2 (the third photoelectric conversion unit) is for the red color (R). Note that the combination of colors is not limited to the above. For example, the organic photoelectric conversion element 43 (the first photoelectric conversion unit) can be for the red or blue color, and the first photodiode 42-1 (the second photoelectric conversion unit) and the second photodiode 42-2 (the third photoelectric conversion unit) can be set for other corresponding colors.

Also, in this embodiment, the first photodiode 42-1 and the second photodiode 42-2 may not be used. Instead, three organic photoelectric conversion elements, which are an organic photoelectric conversion element 43-1 for the blue color (the first photoelectric conversion unit), an organic photoelectric conversion element 43-2 for the green color (the second photoelectric conversion unit), and an organic photoelectric conversion element 43-3 for the red color (the third photoelectric conversion unit) may be applied to the solid-state imaging device of this embodiment. The photoelectric conversion element 43-1 that performs photoelectric conversion at the wavelength of blue light may be an organic photoelectric conversion material containing a coumarin dye, tris-8-hydroxyquinoline Al (Alq3), a merocyanine dye, or the like. The photoelectric conversion element 43-2 that performs photoelectric conversion at the wavelength of green light may be an organic photoelectric conversion material containing a rhodamine dye, a merocyanine dye, quinacridone, or the like, for example. The photoelectric conversion element 43-3 that performs photoelectric conversion at the wavelength of red light may be an organic photoelectric conversion material containing a phthalocyanine dye.

In the solid-state imaging device of this embodiment, the photoelectric conversion layer 432 of the organic photoelectric conversion element 43 corresponding to at least one of the pixels 20 contains a circularly polarized dichroic material. Note that the circularly polarized dichroic material may be any of those mentioned above in <2. First Embodiment>. In a case where three organic photoelectric conversion elements are used without the first photodiode 42-1 and the second photodiode 42-2, the photoelectric conversion layer of one or more of the organic photoelectric conversion elements has circularly polarized dichroism.

Note that, in the solid-state imaging device 10 of this embodiment, one photoelectric conversion unit may include a plurality of organic photoelectric conversion elements 43 that have different sensitivities to circularly polarized light and detect the same color. For example, the first organic photoelectric conversion element 43-1 and the second organic photoelectric conversion element 43-2 stacked in a vertical direction may be used as the photoelectric conversion unit for the green color. In this configuration, the first organic photoelectric conversion element 43-1 may obtain information about left circularly polarized light and the green color, and the second organic photoelectric conversion element 43-2 may obtain information about right circularly polarized light and the green color.

[Operation of the Solid-State Imaging Device 10]

In the description below, operation of the solid-state imaging device 10 of this embodiment is explained.

In FIG. 7, light that has entered the solid-state imaging device 10 is refracted and condensed by the on-chip lens 30, passes through the planarizing layer 31 and the protective layer 32, and is condensed onto the organic photoelectric conversion element 43. Part of the incident light that has passed through the organic photoelectric conversion element 43 passes through the insulating film 33, and is condensed onto the first photodiode 42-1 and the second photodiode 42-2. The light that has entered the organic photoelectric conversion element 43, the first photodiode 42-1, and the second photodiode 42-2 is then photoelectrically converted, and is output as an electrical signal.

As shown in FIG. 7, in a case where the photoelectric conversion layer 432a of a pixel 20a contains a material that preferentially transmits right circularly polarized light, the organic photoelectric conversion element 43a can obtain information about right circularly polarized light and the green color, the first photodiode 42a-1 can obtain information about unpolarized light and the blue color, and the second photodiode 42a-2 can obtain information about unpolarized light and the red color. Meanwhile, in a case where the photoelectric conversion layer 432b of a pixel 20b contains a material that preferentially transmits left circularly polarized light, the organic photoelectric conversion element 43b can obtain information about left circularly polarized light and the green color, the first photodiode 42b-1 can obtain information about unpolarized light and the blue color, and the second photodiode 42b-2 can obtain information about unpolarized light and the red color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

As described above, in the solid-state imaging device 10 of this embodiment, information about an unpolarized or circularly polarized image in three colors can be obtained by one pixel 20.

Note that, in this embodiment, the filter unit 40 may be provided between the organic photoelectric conversion element 43 and the first photodiode 42-1. For example, in a case where an optical filter 401 containing a circularly polarized dichroic material as shown in FIG. 2 is used as the filter unit 40, the organic photoelectric conversion element 43, the first photodiode 42-1, and the second photodiode 42-2 of each pixel 20 can obtain information about three colors having different sensitivities to circularly polarized light between adjacent pixels 20.

(4-2. Front-Illuminated Solid-State Imaging Device)

The solid-state imaging device of this embodiment can be applied not only to a back-illuminated solid-state imaging device but also to a front-illuminated solid-state imaging device. An example of a front-illuminated solid-state imaging device differs from the above back-illuminated solid-state imaging device 10 only in that the wiring layer 202 formed under the semiconductor substrate 41 is formed between the organic photoelectric conversion element 43 and the semiconductor substrate 41. Other aspects may be similar to those of the back-illuminated solid-state imaging device 10 described above, and explanation of them is not made herein.

### 5. Fourth Embodiment (a Modification of the Third Embodiment)

A solid-state imaging device according to a fourth embodiment of the present technology is described. The solid-state imaging device according to this embodiment is a modification of the solid-state imaging device described above in <4. Third Embodiment>.

(5-1. Back-Illuminated Solid-State Imaging Device)

Referring now to FIG. 8, an example of a back-illuminated solid-state imaging device is described. FIG. 8 is a cross-sectional diagram schematically showing an example configuration of a back-illuminated solid-state imaging device according to this embodiment. In a back-illuminated solid-state imaging device 10 of this embodiment, each pixel 20 includes a light receiving unit 201 on a wiring layer 202. In the light receiving unit 201 of each pixel, a first photoelectric conversion unit (an organic photoelectric conversion element 43), a filter unit 40, and a second photoelectric conversion unit (a photodiode 42) are disposed in this order, and an on-chip lens 30 is stacked on the first photoelectric conversion unit (the organic photoelectric conversion element 43) via a protective layer 32 and a planarizing layer 31. In the description below, the respective layers are explained. Note that, in the solid-state imaging device of this embodiment, the basic configurations of the on-chip lens 30, the filter unit 40, the planarizing layer 31, the protective layer 32, the insulating film 33, the photodiodes 42, and the organic photoelectric conversion element 43 are as described above in <2. First Embodiment> and the like, and therefore, explanation of them is not made herein.

The solid-state imaging device 10 of this embodiment has a configuration in which each one pixel 20 includes an organic photoelectric conversion element 43 (a first photoelectric conversion unit), and a photodiode 42 (a second photoelectric conversion unit) having a p-n junction. In the example of the solid-state imaging device shown in FIG. 8, the organic photoelectric conversion element 43 is for the green color (G), and the photodiode 42 detects light of the color component corresponding to the color of the filter unit 40 existing above the photodiode 42. For example, in a case where the filter unit 40a of a pixel 20a includes a blue color filter 402a, the photodiode 42a is for the blue color. In a case where the filter 40b of a pixel 20b includes a red color filter 402b, on the other hand, the photodiode 42b is for the red color.

Also, in this embodiment, the photodiode 42 may not be used. Instead, two organic photoelectric conversion elements that are selected from among an organic photoelectric conversion element 43-1 for the blue color, an organic photoelectric conversion element 43-2 for the green color, and an organic photoelectric conversion element 43-3 for the red color may be applied to each pixel of the solid-state imaging device of this embodiment. The materials that can be used for each photoelectric conversion element are as described above in <4. Third Embodiment>.

In the solid-state imaging device of this embodiment, the photoelectric conversion layer 432 of the organic photoelectric conversion element 43 corresponding to at least one of the pixels 20 contains a circularly polarized dichroic material. Note that the circularly polarized dichroic material may be any of those mentioned above in <2. First Embodiment>. In a case where two organic photoelectric conversion elements are used without the photodiode 42, the photoelectric conversion layer of one or more of the organic photoelectric conversion elements has circularly polarized dichroism.

Note that, in the solid-state imaging device 10 of this embodiment, one photoelectric conversion unit may include a plurality of organic photoelectric conversion elements 43 that have different sensitivities to circularly polarized light and detect the same color. For example, the first organic photoelectric conversion element 43-1 and the second organic photoelectric conversion element 43-2 stacked in a vertical direction may be used as the photoelectric conversion unit for the green color. In this configuration, the first organic photoelectric conversion element 43-1 may obtain information about left circularly polarized light and the green color, and the second organic photoelectric conversion element 43-2 may obtain information about right circularly polarized light and the green color.

[Operation of the Solid-State Imaging Device 10]

In the description below, operation of the solid-state imaging device 10 of this embodiment is explained.

In FIG. 8, light that has entered the solid-state imaging device 10 is refracted and condensed by the on-chip lens 30, passes through the planarizing layer 31 and the protective layer 32, and is condensed onto the organic photoelectric conversion element 43. Part of the incident light that has passed through the organic photoelectric conversion element 43 passes through the filter unit 402, and is condensed onto the photodiode 42. The light that has entered the organic photoelectric conversion element 43 and the photodiode 42 is then photoelectrically converted, and is output as an electrical signal.

As shown in FIG. 8, in a case where the photoelectric conversion layer 432a of the pixel 20a contains a material that preferentially transmits right circularly polarized light, and the filter unit 40a includes the blue color filter 402a, the organic photoelectric conversion element 43a can obtain information about right circularly polarized light and the green color, and the photodiode 42a can obtain information about unpolarized light and the blue color. Meanwhile, in a case where the photoelectric conversion layer 432b of the pixel 20b contains a material that preferentially transmits left circularly polarized light, and the filter 40b of the pixel 20b includes the red color filter 402b, the organic photoelectric conversion element 43b can obtain information about left circularly polarized light and the green color, and the photodiode 42b can obtain information about unpolarized light and the red color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

As described above, in the solid-state imaging device 10 of this embodiment, information about an unpolarized image and a circularly polarized image in two colors can be obtained by one pixel 20.

Note that, although the configuration using the color filter 402 as the filter unit 40 has been described above, it is also possible to adopt a configuration in which an optical filter 401 containing a circularly polarized dichroic material and a color filter 402 are stacked as shown in FIGS. 3 and 4, or a configuration using a color filter 402 containing a circularly polarized dichroic material as shown in FIG. 5. In these cases, the organic photoelectric conversion element 43 and the photodiode 42 of each pixel 20 can obtain information about two colors having different sensitivities to circularly polarized light between adjacent pixels 20.

(5-2. Front-Illuminated Solid-State Imaging Device)

The solid-state imaging device of this embodiment can be applied not only to a back-illuminated solid-state imaging device but also to a front-illuminated solid-state imaging device. An example of a front-illuminated solid-state imaging device differs from the above back-illuminated solid-state imaging device 10 only in that the wiring layer 202 formed under the semiconductor substrate 41 is formed between the color filter 40 and the semiconductor substrate 41. Other aspects may be similar to those of the back-illuminated solid-state imaging device 10 described above, and explanation of them is not made herein.

### 6. Fifth Embodiment (an Example of a Solid-State Imaging Device Containing a Circularly Polarized Dichroic Material in a Panchromatic Photosensitive Organic Photoelectric Conversion Film)

A solid-state imaging device according to a fifth embodiment of the present technology is described. In the solid-state imaging device of this embodiment, the light receiving unit of each pixel includes a filter unit and a photoelectric conversion unit disposed in this order, and the photoelectric conversion unit includes at least one panchromatic photosensitive organic photoelectric conversion film. Further, the panchromatic photosensitive organic photoelectric conversion film included in at least one of the pixels contains a circularly polarized dichroic material.

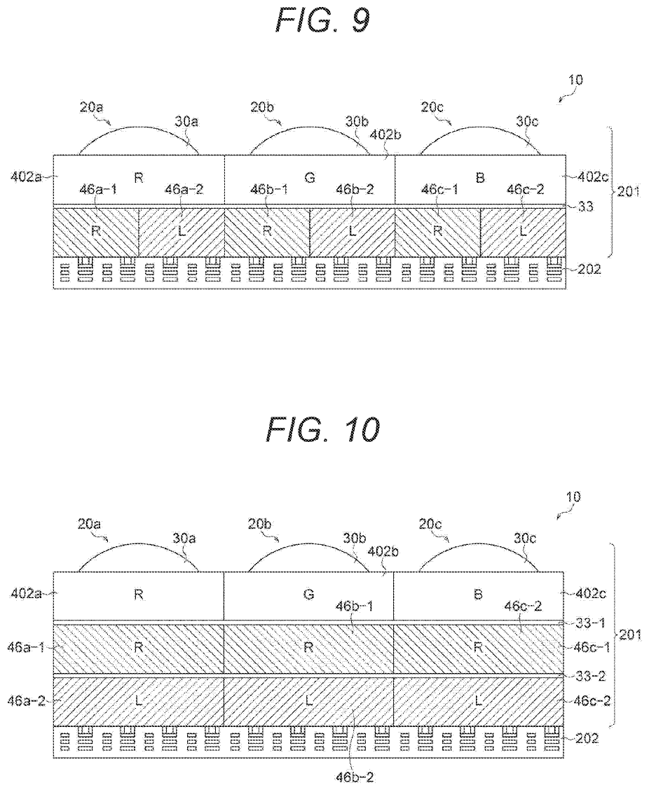

FIG. 9 is a cross-sectional diagram schematically showing an example configuration of a solid-state imaging device according to this embodiment. In a solid-state imaging device 10 of this embodiment, each pixel 20 includes a light receiving unit 201 on a wiring layer 202. The light receiving unit 201 of each pixel has a structure in which a filter unit (a color filter 402) and a photoelectric conversion unit (a panchromatic photosensitive organic photoelectric conversion film 46) are provided. Further, an on-chip lens 30 is stacked on the filter unit (the color filter 402). In the description below, the respective layers are explained. Note that, in the solid-state imaging device of this embodiment, the basic configurations of the on-chip lens 30, the filter unit (the color filter 402), and the insulating film 33 are as described above in <2. First Embodiment> and the like, and therefore, explanation of them is not made herein.

[Panchromatic Photosensitive Organic Photoelectric Conversion Film 46]

The solid-state imaging device 10 of this embodiment has two panchromatic photosensitive organic photoelectric conversion films 46 arranged side by side in each one pixel 20. A panchromatic photosensitive organic photoelectric conversion film is a photoelectric conversion film having sensitivity over the entire visible light wavelength region. Therefore, the color component to be detected by the panchromatic photosensitive organic photoelectric conversion films 46 of each pixel 20 corresponds to the color of the filter unit (the color filter 402) existing above the panchromatic photosensitive organic photoelectric conversion films 46. For example, in a case where a pixel 20a includes a red color filter 402a, the panchromatic photosensitive organic photoelectric conversion films 46a-1 and 46a-2 are for the red color. Likewise, in a case where a pixel 20b includes a green color filter 402b, the panchromatic photosensitive organic photoelectric conversion films 46b-1 and 46b-2 are for the green color. In a case where a pixel 20c includes a blue color filter 402c, the panchromatic photosensitive organic photoelectric conversion films 46c-1 and 46c-2 are for the blue color. Light that has entered the panchromatic photosensitive organic photoelectric conversion films 46 is then photoelectrically converted, and is output as an electrical signal.

In the solid-state imaging device of this embodiment, the panchromatic photosensitive organic photoelectric conversion films 46 corresponding to at least one of the pixels 20 contain a circularly polarized dichroic material. Note that the circularly polarized dichroic material may be any of those mentioned above in <2. First Embodiment>.

[Operation of the Solid-State Imaging Device 10]

In the description below, operation of the solid-state imaging device 10 of this embodiment is explained.

In FIG. 9, light that has entered the solid-state imaging device 10 is refracted and condensed by the on-chip lens 30, and enters the filter unit (the color filter 402). The incident light that has passed through the filter unit (the color filter 402) passes through the insulating film 33, and is condensed onto the panchromatic photosensitive organic photoelectric conversion films 46. The light that has entered the panchromatic photosensitive organic photoelectric conversion films 46 is then photoelectrically converted, and is output as an electrical signal.

As shown in FIG. 9, in a case where the color filter 402a of the pixel 20a is for the red color, the first panchromatic photosensitive organic photoelectric conversion film 46a-1 contains a material that preferentially transmits right circularly polarized light, and the second panchromatic photosensitive organic photoelectric conversion film 46a-2 contains a material that preferentially transmits left circularly polarized light, the first panchromatic photosensitive organic photoelectric conversion film 46a-1 can obtain information about right circularly polarized light and the red color, and the second panchromatic photosensitive organic photoelectric conversion film 46a-2 can obtain information about left circularly polarized light and the red color. Likewise, in a case where the color filter 402b of the pixel 20b is for the green color, the first panchromatic photosensitive organic photoelectric conversion film 46b-1 contains a material that preferentially transmits right circularly polarized light, and the second panchromatic photosensitive organic photoelectric conversion film 46b-2 contains a material that preferentially transmits left circularly polarized light, the first panchromatic photosensitive organic photoelectric conversion film 46b-1 can obtain information about right circularly polarized light and the green color, and the second panchromatic photosensitive organic photoelectric conversion film 46b-2 can obtain information about left circularly polarized light and the green color. Further, in a case where the color filter 402c of the pixel 20c is for the blue color, the first panchromatic photosensitive organic photoelectric conversion film 46c-1 contains a material that preferentially transmits right circularly polarized light, and the second panchromatic photosensitive organic photoelectric conversion film 46c-2 contains a material that preferentially transmits left circularly polarized light, the first panchromatic photosensitive organic photoelectric conversion film 46c-1 can obtain information about right circularly polarized light and the blue color, and the second panchromatic photosensitive organic photoelectric conversion film 46c-2 can obtain information about left circularly polarized light and the blue color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

As described above, in the solid-state imaging device 10 of this embodiment, two kinds of circularly polarized image information can be obtained by one pixel 20.

### 7. Sixth Embodiment (a Modification of the Fifth Embodiment)

A solid-state imaging device according to a sixth embodiment of the present technology is described. The solid-state imaging device according to this embodiment is a modification of the solid-state imaging device described above in <6. Fifth Embodiment>.

FIG. 10 is a cross-sectional diagram schematically showing an example configuration of a solid-state imaging device according to this embodiment. In a solid-state imaging device 10 of this embodiment, each pixel 20 includes a light receiving unit 201 on a wiring layer 202. The light receiving unit 201 of each pixel has a structure in which a filter unit (a color filter 402) and a plurality of photoelectric conversion units (a first panchromatic photosensitive organic photoelectric conversion film 46-1 and a second panchromatic photosensitive organic photoelectric conversion film 46-2) are provided. Further, an on-chip lens 30 is disposed on the filter unit (the color filter 402). In the description below, the respective layers are explained. Note that, in the solid-state imaging device of this embodiment, the basic configurations of the on-chip lens 30, the filter unit (the color filter 402), the insulating films 33, and the panchromatic photosensitive organic photoelectric conversion films 46 are as described above in <2. First Embodiment>, and therefore, explanation of them is not made herein.

The solid-state imaging device 10 of this embodiment has two panchromatic photosensitive organic photoelectric conversion films 46 stacked in a vertical direction in each one pixel 20.

Further, in the solid-state imaging device of this embodiment, the panchromatic photosensitive organic photoelectric conversion films 46 corresponding to at least one of the pixels 20 contain a circularly polarized dichroic material. Note that the circularly polarized dichroic material may be any of those mentioned above in <2. First Embodiment>.

[Operation of the Solid-State Imaging Device 10]

In the description below, operation of the solid-state imaging device 10 of this embodiment is explained.

In FIG. 10, light that has entered the solid-state imaging device 10 is refracted and condensed by the on-chip lens 30, and enters the filter unit (the color filter 402). The incident light that has passed through the filter unit (the color filter 402) passes through the insulating film 33-1, and is condensed onto the first panchromatic photosensitive organic photoelectric conversion film 46-1. Part of the incident light that has passed through the first panchromatic photosensitive organic photoelectric conversion film 46-1 then passes through the insulating film 33-2, and enters the second panchromatic photosensitive organic photoelectric conversion film 46-2. The light that has passed through the first panchromatic photosensitive organic photoelectric conversion film 46-1 and the second panchromatic photosensitive organic photoelectric conversion film 46-2 is photoelectrically converted, and is output as an electrical signal.

As shown in FIG. 10, in a case where the color filter 402a of the pixel 20a is for the red color, the first panchromatic photosensitive organic photoelectric conversion film 46a-1 contains a material that preferentially transmits right circularly polarized light, and the second panchromatic photosensitive organic photoelectric conversion film 46a-2 contains a material that preferentially transmits left circularly polarized light, the first panchromatic photosensitive organic photoelectric conversion film 46a-1 can obtain information about right circularly polarized light and the red color, and the second panchromatic photosensitive organic photoelectric conversion film 46a-2 can obtain information about left circularly polarized light and the red color. Likewise, in a case where the color filter 402b of the pixel 20b is for the green color, the first panchromatic photosensitive organic photoelectric conversion film 46b-1 contains a material that preferentially transmits right circularly polarized light, and the second panchromatic photosensitive organic photoelectric conversion film 46b-2 contains a material that preferentially transmits left circularly polarized light, the first panchromatic photosensitive organic photoelectric conversion film 46b-1 can obtain information about right circularly polarized light and the green color, and the second panchromatic photosensitive organic photoelectric conversion film 46b-2 can obtain information about left circularly polarized light and the green color. Further, in a case where the color filter 402c of the pixel 20c is for the blue color, the first panchromatic photosensitive organic photoelectric conversion film 46c-1 contains a material that preferentially transmits right circularly polarized light, and the second panchromatic photosensitive organic photoelectric conversion film 46c-2 contains a material that preferentially transmits left circularly polarized light, the first panchromatic photosensitive organic photoelectric conversion film 46c-1 can obtain information about right circularly polarized light and the blue color, and the second panchromatic photosensitive organic photoelectric conversion film 46c-2 can obtain information about left circularly polarized light and the blue color.

Furthermore, it is possible to obtain a desired circularly polarized image by interpolating information in each pixel obtained in the solid-state imaging device 10 of this embodiment by the method described later in <8. Seventh Embodiment (an Imaging Apparatus)>.

As described above, in the solid-state imaging device 10 of this embodiment, two kinds of circularly polarized image information can be obtained by one pixel 20.

### 8. Seventh Embodiment (Imaging Apparatus)

An imaging apparatus of a seventh embodiment according to the present technology is an imaging apparatus that includes at least a solid-state imaging device of one of the first to sixth embodiments described above, and a signal processing unit that generates an image capturing only specific circularly polarized light on the basis of a signal obtained from at least one of the pixels of the solid-state imaging device.

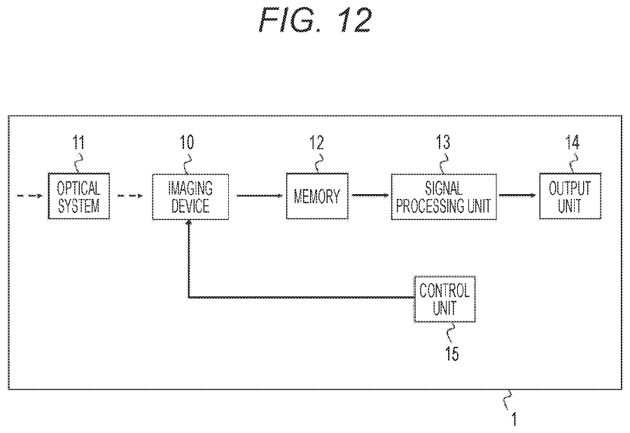

FIG. 12 is a block diagram showing an example configuration of the imaging apparatus of this embodiment. An imaging apparatus 1 of this embodiment includes a solid-state imaging device 10 described above in one the first to sixth embodiments, an optical system 11 that causes light to enter the solid-state imaging device 10, a memory 12, a signal processing unit 13, an output unit 14, and a control unit 15. In the description below, the respective components are explained.

[Optical System 11]

The optical system 11 includes a zoom lens, a focus lens, and a diaphragm, for example, and causes light from outside to enter the solid-state imaging device 10.

[Memory 12]

The memory 12 temporarily stores image data the solid-state imaging device 10 has output.

[Signal Processing Unit 13]

The signal processing unit 13 performs signal processing (processing such as denoising and white balance adjustment, for example) using the image data stored in the memory 12. The signal processing unit 13 generates an image of only specific circularly polarized light and/or an unpolarized image, on the basis of information obtained by the solid-state imaging device 10 of the first to sixth embodiments.

The signal processing unit 13 can generate an image of only a specific circularly polarized light component or generate an unpolarized image by a method disclosed in Japanese Patent Application Laid-Open No. 2017-038011, for example. Also, information in each pixel can be interpolated on the basis of information between adjacent pixels by a known method such as a demosaicing process, for example.

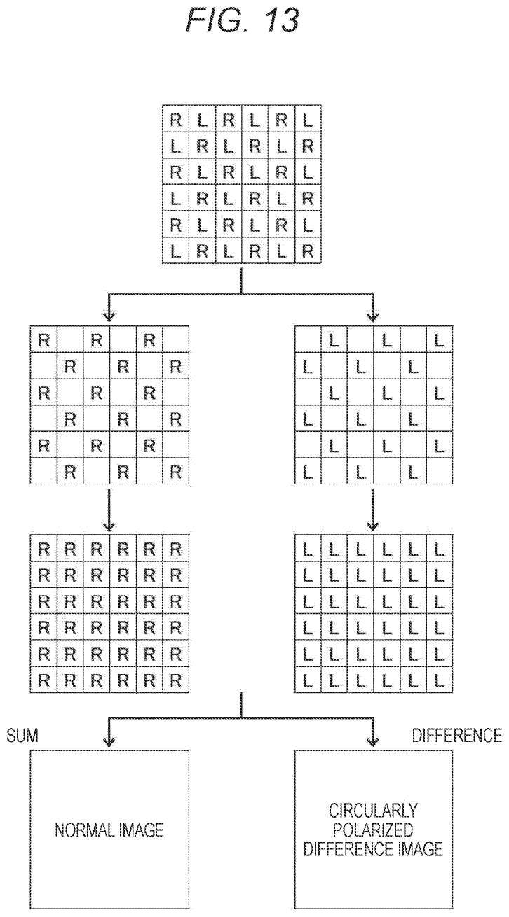

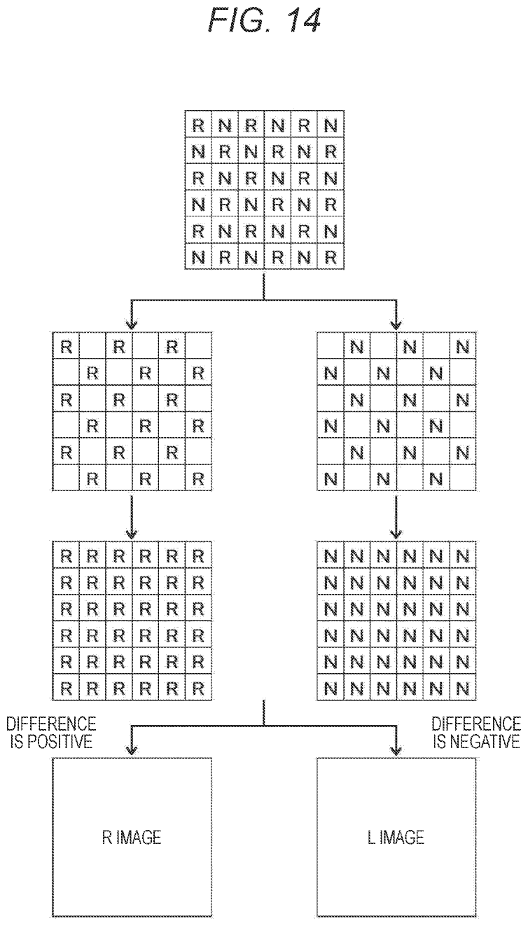

FIGS. 13 and 14 are schematic diagrams each illustrating an example method for generating a circularly polarized image or an unpolarized image, using the imaging apparatus of this embodiment.

FIG. 13 is a schematic diagram in a case where a filter unit or a photoelectric conversion unit in which portions (“R”) containing a material that preferentially transmits right circularly polarized light and portions (“L”) containing a material that preferentially transmits left circularly polarized light are alternately arranged for the respective pixels is used as a filter unit or a photoelectric conversion unit described in the first to sixth embodiments. First, the signal processing unit 13 separates images of right circularly polarized light and left circularly polarized light obtained from the solid-state imaging device 10 into information only about right circularly polarized light and information only about left circularly polarized light. Next, the signal processing unit 13 performs an interpolation process on each pixel having no polarization information, on the basis of information between adjacent pixels, and generates a right circularly polarized image and a left circularly polarized image. Note that an image calculation may be then performed, to generate a normal image from the sum of the right circularly polarized image and the left circularly polarized image, and a circularly polarized difference image from the difference between the right circularly polarized image and the left circularly polarized image.

On the other hand, FIG. 14 is a schematic diagram in a case where a filter unit or a photoelectric conversion unit in which portions (“R”) containing a material that preferentially transmits right circularly polarized light and portions (“N”) not containing any circularly polarized dichroic material are alternately arranged for the respective pixels is used as a filter unit or a photoelectric conversion unit described in the first to sixth embodiments. First, the signal processing unit 13 separates images of right circularly polarized light and unpolarized light (not depending on the type of circularly polarized light) obtained from the solid-state imaging device 10, into information only about right circularly polarized light and information only about unpolarized light. Next, the signal processing unit 13 performs an interpolation process on each pixel having no polarization information, on the basis of information between adjacent pixels, and generates a right circularly polarized image and an unpolarized image. Note that image calculation may be then performed, to generate a right circularly polarized image from a portion in which the difference between the right circularly polarized image and the non-polarized image is positive, and generate a left circularly polarized image from a portion in which the difference between the right circularly polarized image and the unpolarized image is negative.

[Output Unit 14]

The output unit 14 outputs the image data supplied from the signal processing unit 13. For example, the output unit 14 includes a display formed with liquid crystal or the like, and displays the image data supplied from the signal processing unit 13. The output unit 14 also includes a driver for driving a recording medium such as a semiconductor memory, a magnetic disk, or an optical disk, for example, and records the image data supplied from the signal processing unit 13 on the recording medium. The output unit 14 further functions as a communication interface that communicates with an external device, for example, and transmits the image data supplied from the signal processing unit 13 to the external device in a wireless or wired manner.

[Control Unit 15]

The control unit 15 controls the respective components of the imaging apparatus 1, in accordance with a user operation or the like. For example, the control unit 15 outputs a drive signal for controlling an operation of transferring the signal charges accumulated in the solid-state imaging device 10 to the signal processing unit 13. The control unit 15 also outputs a drive signal for controlling a shutter operation of a shutter device (not shown), for example.

[Examples of Use of the Imaging Apparatus 1]

In the description below, examples of use of the imaging apparatus 1 are explained.

For example, in a case where the polarization characteristics of the target object are known, and any unpolarized image is unnecessary, as in the case of product inspection or the like, it is possible to obtain a right circularly polarized image or a left circularly polarized image by using, as a filter unit or a photoelectric conversion unit described in the first to sixth embodiments, a filter unit or a photoelectric conversion unit containing a material that preferentially transmits right circularly polarized light or a material that preferentially transmits left circularly polarized light in the portions corresponding to all the pixels.

Further, in a case where the polarization characteristics of the target object are unknown, as in the case of medical use or the like, for example, it is possible to obtain a right circularly polarized image, a left circularly polarized image, an unpolarized image, and the difference between the right circularly polarized image and the left circularly polarized image, by using, as a filter unit or a photoelectric conversion unit described in the first to sixth embodiments, a filter unit or a photoelectric conversion unit in which portions containing a material that preferentially transmits right circularly polarized light and portions containing a material that preferentially transmits left circularly polarized light are alternately arranged.

Alternatively, in a case where a polarized image is to be obtained as auxiliary information in addition to an unpolarized image, as in the case of medical use or the like, it is possible to obtain a right circularly polarized image, a left circularly polarized image, an unpolarized image, and the difference between the right circularly polarized image and the left circularly polarized image, by using, as a filter unit or a photoelectric conversion unit described in the first to sixth embodiments, a filter unit or a photoelectric conversion unit in which portions containing a material that preferentially transmits right circularly polarized light, portions containing a material that preferentially transmits left circularly polarized light, and portions not containing any circularly polarized dichroic material are alternately arranged.

Further, in a case where a polarized image and an unpolarized image of the target object are to be obtained, as in the case of landscape imaging or the like, for example, it is possible to obtain a right circularly polarized image or a left circularly polarized image, and an unpolarized image by using, as a filter unit or a photoelectric conversion unit described in the first to sixth embodiments, a filter unit or a photoelectric conversion unit in which portions containing a material that preferentially transmits right circularly polarized light or a material that preferentially transmits left circularly polarized light, and portions not containing any circularly polarized dichroic material are alternately arranged.

### 9. Examples of Use of Solid-State Imaging Devices to which the Present Technology is Applied

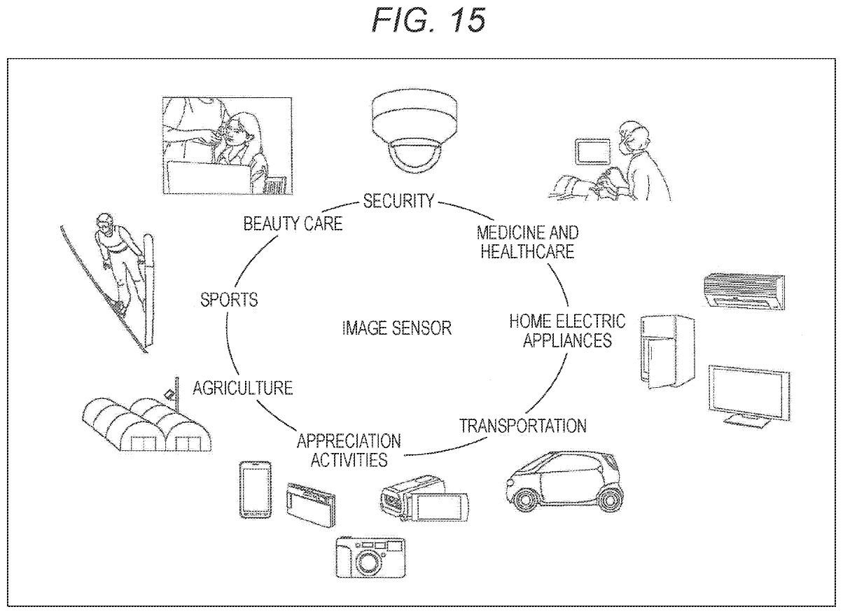

FIG. 15 is a diagram showing examples of use of solid-state imaging devices of the first to sixth embodiments according to the present technology as image sensors.

Solid-state imaging devices of the first to sixth embodiments described above can be used in various cases where light such as visible light, infrared light, ultraviolet light, or an X-ray is sensed, as described below, for example. That is, as shown in FIG. 15, solid-state imaging devices of the first to sixth embodiments can be used in apparatuses (such as the imaging apparatus of the seventh embodiment described above, for example) that are used in the appreciation activity field where images are taken and are used in appreciation activities, the field of transportation, the field of home electric appliances, the fields of medicine and healthcare, the field of security, the field of beauty care, the field of sports, the field of agriculture, and the like, for example.

Specifically, in the appreciation activity field, a solid-state imaging device of the first to sixth embodiments can be used in an apparatus for capturing images to be used in appreciation activities, such as a digital camera, a smartphone, or a portable telephone with a camera function, for example.

In the field of transportation, a solid-state imaging device of any one of the first to sixth embodiments can be used in an apparatus for transportation use, such as a vehicle-mounted sensor designed to capture images of the front, the back, the surroundings, the inside, and the like of an automobile, to perform safe driving such as an automatic stop and recognize the driver's condition or the like, a surveillance camera for monitoring running vehicles and roads, and a ranging sensor or the like for measuring distances between vehicles or the like, for example.

In the field of home electric appliances, a solid-state imaging device of any one of the first to sixth embodiments can be used in an apparatus to be used as home electric appliances, such as a television set, a refrigerator, or an air conditioner, to capture images of gestures of users and operate the apparatus in accordance with the gestures, for example.

In the fields of medicine and healthcare, a solid-state imaging device of any one of the first to sixth embodiments can be used in an apparatus for medical use or healthcare use, such as an endoscope or an apparatus for receiving infrared light for angiography, for example.

In the field of security, a solid-state imaging device of any one of the first to sixth embodiments can be used in an apparatus for security use, such as a surveillance camera for crime prevention or a camera for personal authentication, for example.

In the field of beauty care, a solid-state imaging device of any one of the first to sixth embodiments can be used in an apparatus for beauty care use, such as a skin measurement apparatus designed to capture images of the skin or a microscope for capturing images of the scalp, for example.

In the field of sports, a solid-state imaging device of any one of the first to sixth embodiments can be used in an apparatus for sporting use, such as an action camera or a wearable camera for sports or the like, for example.

In the field of agriculture, a solid-state imaging device of the first to sixth embodiments can be used in an apparatus for agricultural use, such as a camera for monitoring conditions of fields and crops, for example.

### 10. Example Application to an Endoscopic Surgery System

The present technology can be applied to various products. For example, the technology (the present technology) according to the present disclosure may be applied to an endoscopic surgery system.

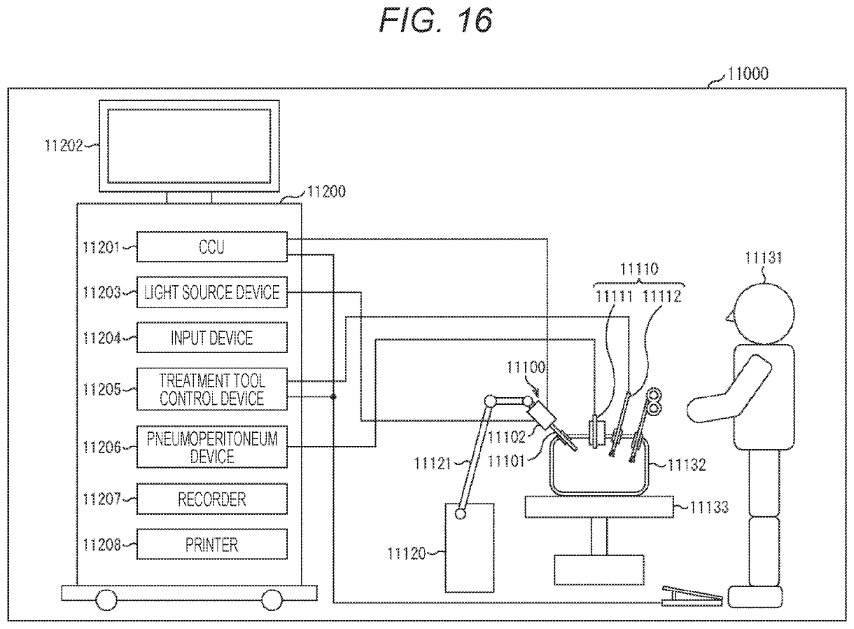

FIG. 16 is a diagram schematically showing an example configuration of an endoscopic surgery system to which the technology (the present technology) according to the present disclosure can be applied.

FIG. 16 shows a situation where a surgeon (a physician) 11131 is performing surgery on a patient 11132 on a patient bed 11133, using an endoscopic surgery system 11000. As shown in the drawing, the endoscopic surgery system 11000 includes an endoscope 11100, other surgical tools 11110 such as a pneumoperitoneum tube 11111 and an energy treatment tool 11112, a support arm device 11120 that supports the endoscope 11100, and a cart 11200 on which various kinds of devices for endoscopic surgery are mounted.

The endoscope 11100 includes a lens barrel 11101 that has a region of a predetermined length from the top end to be inserted into a body cavity of the patient 11132, and a camera head 11102 connected to the base end of the lens barrel 11101. In the example shown in the drawing, the endoscope 11100 is designed as a so-called rigid scope having a rigid lens barrel 11101. However, the endoscope 11100 may be designed as a so-called flexible scope having a flexible lens barrel.

At the top end of the lens barrel 11101, an opening into which an objective lens is inserted is provided. A light source device 11203 is connected to the endoscope 11100, and the light generated by the light source device 11203 is guided to the top end of the lens barrel by a light guide extending inside the lens barrel 11101, and is emitted toward the current observation target in the body cavity of the patient 11132 via the objective lens. Note that the endoscope 11100 may be a forward-viewing endoscope, an oblique-viewing endoscope, or a side-viewing endoscope.

An optical system and an imaging device are provided inside the camera head 11102, and reflected light (observation light) from the current observation target is converged on the imaging device by the optical system. The observation light is photoelectrically converted by the imaging device, and an electrical signal corresponding to the observation light, or an image signal corresponding to the observation image, is generated. The image signal is transmitted as RAW data to a camera control unit (CCU) 11201.

The CCU 11201 is formed with a central processing unit (CPU), a graphics processing unit (GPU), or the like, and collectively controls operations of the endoscope 11100 and a display device 11202. Further, the CCU 11201 receives an image signal from the camera head 11102, and subjects the image signal to various kinds of image processing, such as a development process (a demosaicing process), for example, to display an image based on the image signal.

Under the control of the CCU 11201, the display device 11202 displays an image based on the image signal subjected to the image processing by the CCU 11201.

The light source device 11203 is formed with a light source such as a light emitting diode (LED), for example, and supplies the endoscope 11100 with illuminating light for imaging the surgical site or the like.

An input device 11204 is an input interface to the endoscopic surgery system 11000. The user can input various kinds of information and instructions to the endoscopic surgery system 11000 via the input device 11204. For example, the user inputs an instruction or the like to change imaging conditions (such as the type of illuminating light, the magnification, and the focal length) for the endoscope 11100.

A treatment tool control device 11205 controls driving of the energy treatment tool 11112 for tissue cauterization, incision, blood vessel sealing, or the like. A pneumoperitoneum device 11206 injects a gas into a body cavity of the patient 11132 via the pneumoperitoneum tube 11111 to inflate the body cavity, for the purpose of securing the field of view of the endoscope 11100 and the working space of the surgeon. A recorder 11207 is a device capable of recording various kinds of information regarding the surgery. A printer 11208 is a device capable of printing various kinds of information regarding the surgery in various formats such as text, images, and graphics.

Note that the light source device 11203 that supplies the endoscope 11100 with the illuminating light for imaging the surgical site can be formed with an LED, a laser light source, or a white light source that is a combination of an LED and a laser light source, for example. In a case where a white light source is formed with a combination of RGB laser light sources, the output intensity and the output timing of each color (each wavelength) can be controlled with high precision. Accordingly, the white balance of an image captured by the light source device 11203 can be adjusted. Alternatively, in this case, laser light from each of the RGB laser light sources may be emitted onto the current observation target in a time-division manner, and driving of the imaging device of the camera head 11102 may be controlled in synchronization with the timing of the light emission. Thus, images corresponding to the respective RGB colors can be captured in a time-division manner. According to the method, a color image can be obtained without any color filter provided in the imaging device.

Further, the driving of the light source device 11203 may also be controlled so that the intensity of light to be output is changed at predetermined time intervals. The driving of the imaging device of the camera head 11102 is controlled in synchronism with the timing of the change in the intensity of the light, and images are acquired in a time-division manner and are then combined. Thus, a high dynamic range image with no black portions and no white spots can be generated.

Further, the light source device 11203 may also be designed to be capable of supplying light of a predetermined wavelength band compatible with special light observation. In special light observation, light of a narrower band than the illuminating light (or white light) at the time of normal observation is emitted, with the wavelength dependence of light absorption in body tissue being taken advantage of, for example. As a result, so-called narrow band light observation (narrow band imaging) is performed to image predetermined tissue such as a blood vessel in a mucosal surface layer or the like, with high contrast. Alternatively, in the special light observation, fluorescence observation for obtaining an image with fluorescence generated through emission of excitation light may be performed. In fluorescence observation, excitation light is emitted to body tissue so that the fluorescence from the body tissue can be observed (autofluorescence observation). Alternatively, a reagent such as indocyanine green (ICG) is locally injected into body tissue, and excitation light corresponding to the fluorescence wavelength of the reagent is emitted to the body tissue so that a fluorescent image can be obtained, for example. The light source device 11203 can be designed to be capable of supplying narrow band light and/or excitation light compatible with such special light observation.

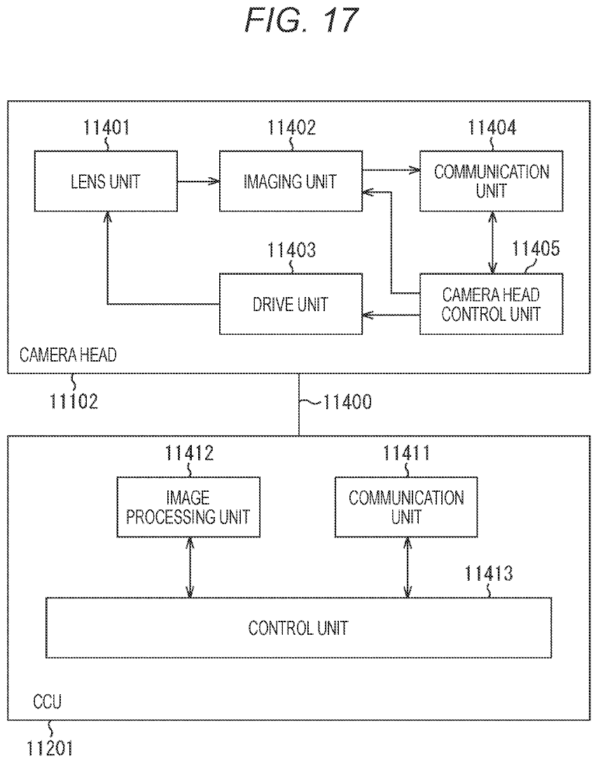

FIG. 17 is a block diagram showing an example of the functional configurations of the camera head 11102 and the CCU 11201 shown in FIG. 16.

The camera head 11102 includes a lens unit 11401, an imaging unit 11402, a drive unit 11403, a communication unit 11404, and a camera head control unit 11405. The CCU 11201 includes a communication unit 11411, an image processing unit 11412, and a control unit 11413. The camera head 11102 and the CCU 11201 are communicably connected to each other by a transmission cable 11400.

The lens unit 11401 is an optical system provided at the connecting portion with the lens barrel 11101. Observation light captured from the top end of the lens barrel 11101 is guided to the camera head 11102, and enters the lens unit 11401. The lens unit 11401 is formed with a combination of a plurality of lenses including a zoom lens and a focus lens.

The imaging unit 11402 is formed with an imaging device. The imaging unit 11402 may be formed with one imaging device (a so-called single-plate type), or may be formed with a plurality of imaging devices (a so-called multiple-plate type). In a case where the imaging unit 11402 is of a multiple-plate type, for example, image signals corresponding to the respective RGB colors may be generated by the respective imaging devices, and be then combined to obtain a color image. Alternatively, the imaging unit 11402 may be designed to include a pair of imaging devices for acquiring right-eye and left-eye image signals compatible with three-dimensional (3D) display. As the 3D display is conducted, the surgeon 11131 can grasp more accurately the depth of the body tissue at the surgical site. Note that, in a case where the imaging unit 11402 is of a multiple-plate type, a plurality of lens units 11401 is provided for the respective imaging devices.

Further, the imaging unit 11402 is not necessarily provided in the camera head 11102. For example, the imaging unit 11402 may be provided immediately behind the objective lens in the lens barrel 11101.

The drive unit 11403 is formed with an actuator, and, under the control of the camera head control unit 11405, moves the zoom lens and the focus lens of the lens unit 11401 by a predetermined distance along the optical axis. With this arrangement, the magnification and the focal point of the image captured by the imaging unit 11402 can be adjusted as appropriate.

The communication unit 11404 is formed with a communication device for transmitting and receiving various kinds of information to and from the CCU 11201. The communication unit 11404 transmits the image signal obtained as RAW data from the imaging unit 11402 to the CCU 11201 via the transmission cable 11400.

The communication unit 11404 also receives a control signal for controlling the driving of the camera head 11102 from the CCU 11201, and supplies the control signal to the camera head control unit 11405. The control signal includes information regarding imaging conditions, such as information for specifying the frame rate of captured images, information for specifying the exposure value at the time of imaging, and/or information for specifying the magnification and the focal point of captured images, for example.

Note that the above imaging conditions such as the frame rate, the exposure value, the magnification, and the focal point may be appropriately specified by the user, or may be automatically set by the control unit 11413 of the CCU 11201 on the basis of an acquired image signal. In the latter case, the endoscope 11100 has a so-called auto-exposure (AE) function, an auto-focus (AF) function, and an auto-white-balance (AWB) function.

The camera head control unit 11405 controls the driving of the camera head 11102, on the basis of a control signal received from the CCU 11201 via the communication unit 11404.

The communication unit 11411 is formed with a communication device for transmitting and receiving various kinds of information to and from the camera head 11102. The communication unit 11411 receives an image signal transmitted from the camera head 11102 via the transmission cable 11400.

Further, the communication unit 11411 also transmits a control signal for controlling the driving of the camera head 11102, to the camera head 11102. The image signal and the control signal can be transmitted through electrical communication, optical communication, or the like.

The image processing unit 11412 performs various kinds of image processing on an image signal that is RAW data transmitted from the camera head 11102.

The control unit 11413 performs various kinds of control relating to display of an image of the surgical portion or the like captured by the endoscope 11100, and a captured image obtained through imaging of the surgical site or the like. For example, the control unit 11413 generates a control signal for controlling the driving of the camera head 11102.

Further, the control unit 11413 also causes the display device 11202 to display a captured image showing the surgical site or the like, on the basis of the image signal subjected to the image processing by the image processing unit 11412. In doing so, the control unit 11413 may recognize the respective objects shown in the captured image, using various image recognition techniques. For example, the control unit 11413 can detect the shape, the color, and the like of the edges of an object shown in the captured image, to recognize a surgical tool such as forceps, a specific body site, bleeding, or the mist at the time of use of the energy treatment tool 11112. When causing the display device 11202 to display the captured image, the control unit 11413 may cause the display device 11202 to superimpose various kinds of surgery aid information on the image of the surgical site on the display, using the recognition result. As the surgery aid information is superimposed and displayed, and thus, is presented to the surgeon 11131, it becomes possible to reduce the burden on the surgeon 11131, and enable the surgeon 11131 to proceed with the surgery in a reliable manner.

The transmission cable 11400 connecting the camera head 11102 and the CCU 11201 is an electrical signal cable compatible with electric signal communication, an optical fiber compatible with optical communication, or a composite cable thereof.

Here, in the example shown in the drawing, communication is performed in a wired manner using the transmission cable 11400. However, communication between the camera head 11102 and the CCU 11201 may be performed in a wireless manner.

An example of an endoscopic surgery system to which the technique according to the present disclosure can be applied has been described above. The technology according to the present disclosure may be applied to the endoscope 11100, (the imaging unit 11402 of) the camera head 11102, and the like in the configuration described above. Specifically, a solid-state imaging device of the present technology can be applied to the imaging unit 10402, for example. As the technology according to the present disclosure is applied to the endoscope 11100, (the imaging unit 11402 of) the camera head 11102, and the like, it is possible to improve the quality and the like of the endoscope 11100, (the imaging unit 11402 of) the camera head 11102, and the like.

Although the endoscopic surgery system has been described as an example herein, the technology according to the present disclosure may be applied to a microscopic surgery system or the like, for example.

### 11. Example Applications to Mobile Structures

The technology (the present technology) according to the present disclosure can be applied to various products. For example, the technology according to the present disclosure may be embodied as a device mounted on any type of mobile structure, such as an automobile, an electrical vehicle, a hybrid electrical vehicle, a motorcycle, a bicycle, a personal mobility device, an airplane, a drone, a vessel, or a robot.

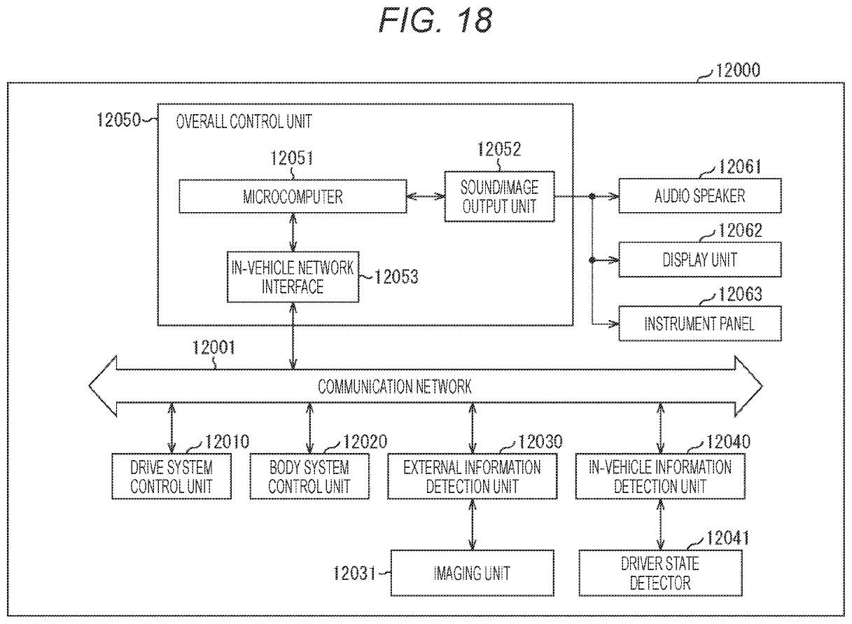

FIG. 18 is a block diagram schematically showing an example configuration of a vehicle control system that is an example of a mobile structure control system to which the technology according to the present disclosure may be applied.

A vehicle control system 12000 includes a plurality of electronic control units connected via a communication network 12001. In the example shown in FIG. 18, the vehicle control system 12000 includes a drive system control unit 12010, a body system control unit 12020, an external information detection unit 12030, an in-vehicle information detection unit 12040, and an overall control unit 12050. Further, a microcomputer 12051, a sound/image output unit 12052, and an in-vehicle network interface (I/F) 12053 are shown as the functional components of the overall control unit 12050.

The drive system control unit 12010 controls operations of the devices related to the drive system of the vehicle according to various programs. For example, the drive system control unit 12010 functions as control devices such as a driving force generation device for generating a driving force of the vehicle such as an internal combustion engine or a driving motor, a driving force transmission mechanism for transmitting the driving force to the wheels, a steering mechanism for adjusting the steering angle of the vehicle, and a braking device for generating a braking force of the vehicle.

The body system control unit 12020 controls operations of the various devices mounted on the vehicle body according to various programs. For example, the body system control unit 12020 functions as a keyless entry system, a smart key system, a power window device, or a control device for various lamps such as a headlamp, a backup lamp, a brake lamp, or a turn signal lamp, a fog lamp. In this case, the body system control unit 12020 can receive radio waves transmitted from a portable device that substitutes for a key, or signals from various switches. The body system control unit 12020 receives inputs of these radio waves or signals, and controls the door lock device, the power window device, the lamps, and the like of the vehicle.

The external information detection unit 12030 detects information outside the vehicle equipped with the vehicle control system 12000. For example, an imaging unit 12031 is connected to the external information detection unit 12030. The external information detection unit 12030 causes the imaging unit 12031 to capture an image of the outside of the vehicle, and receives the captured image. On the basis of the received image, the external information detection unit 12030 may perform an object detection process for detecting a person, a vehicle, an obstacle, a sign, characters on the road surface, or the like, or perform a distance detection process.

The imaging unit 12031 is an optical sensor that receives light, and outputs an electrical signal corresponding to the amount of received light. The imaging unit 12031 can output an electrical signal as an image, or output an electrical signal as distance measurement information. Further, the light to be received by the imaging unit 12031 may be visible light, or may be invisible light such as infrared rays.

The in-vehicle information detection unit 12040 detects information about the inside of the vehicle. For example, a driver state detector 12041 that detects the state of the driver is connected to the in-vehicle information detection unit 12040. The driver state detector 12041 includes a camera that captures an image of the driver, for example, and, on the basis of detected information input from the driver state detector 12041, the in-vehicle information detection unit 12040 may calculate the degree of fatigue or the degree of concentration of the driver, or determine whether or not the driver is dozing off.

On the basis of the external/internal information acquired by the external information detection unit 12030 or the in-vehicle information detection unit 12040, the microcomputer 12051 can calculate the control target value of the driving force generation device, the steering mechanism, or the braking device, and output a control command to the drive system control unit 12010. For example, the microcomputer 12051 can perform cooperative control to achieve the functions of an advanced driver assistance system (ADAS), including vehicle collision avoidance or impact mitigation, follow-up running based on the distance between vehicles, vehicle velocity maintenance running, vehicle collision warning, vehicle lane deviation warning, or the like.

Further, the microcomputer 12051 can also perform cooperative control to conduct automatic driving or the like for autonomously running not depending on the operation of the driver, by controlling the driving force generation device, the steering mechanism, the braking device, or the like on the basis of information about the surroundings of the vehicle, the information having being acquired by the external information detection unit 12030 or the in-vehicle information detection unit 12040.

The microcomputer 12051 can also output a control command to the body system control unit 12020, on the basis of the external information acquired by the external information detection unit 12030. For example, the microcomputer 12051 controls the headlamp in accordance with the position of the leading vehicle or the oncoming vehicle detected by the external information detection unit 12030, and performs cooperative control to achieve an anti-glare effect by switching from a high beam to a low beam, or the like.

The sound/image output unit 12052 transmits an audio output signal and/or an image output signal to an output device that is capable of visually or audibly notifying the passenger(s) of the vehicle or the outside of the vehicle of information. In the example shown in FIG. 18, an audio speaker 12061, a display unit 12062, and an instrument panel 12063 are shown as output devices. The display unit 12062 may include an on-board display and/or a head-up display, for example.

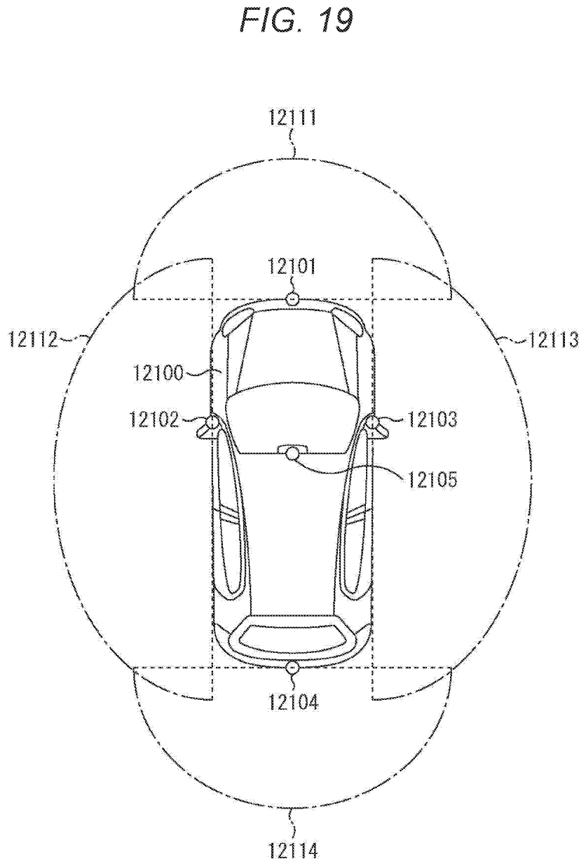

FIG. 19 is a diagram showing an example of installation positions of imaging units 12031.

In FIG. 19, a vehicle 12100 includes imaging units 12101, 12102, 12103, 12104, and 12105 as the imaging units 12031.

Imaging units 12101, 12102, 12103, 12104, and 12105 are provided at the following positions: the front end edge of a vehicle 12100, a side mirror, the rear bumper, a rear door, an upper portion of the front windshield inside the vehicle, and the like, for example. The imaging unit 12101 provided on the front end edge and the imaging unit 12105 provided on the upper portion of the front windshield inside the vehicle mainly capture images ahead of the vehicle 12100. The imaging units 12102 and 12103 provided on the side mirrors mainly capture images on the sides of the vehicle 12100. The imaging unit 12104 provided on the rear bumper or a rear door mainly captures images behind the vehicle 12100. The front images acquired by the imaging units 12101 and 12105 are mainly used for detection of a vehicle running in front of the vehicle 12100, a pedestrian, an obstacle, a traffic signal, a traffic sign, a lane, or the like.

Note that FIG. 19 shows an example of the imaging ranges of the imaging units 12101 to 12104. An imaging range 12111 indicates the imaging range of the imaging unit 12101 provided on the front end edge, imaging ranges 12112 and 12113 indicate the imaging ranges of the imaging units 12102 and 12103 provided on the respective side mirrors, and an imaging range 12114 indicates the imaging range of the imaging unit 12104 provided on the rear bumper or a rear door. For example, images captured from image data by the imaging units 12101 to 12104 are superimposed on one another, so that an overhead image of the vehicle 12100 viewed from above is obtained.

At least one of the imaging units 12101 to 12104 may have a function of acquiring distance information. For example, at least one of the imaging units 12101 to 12104 may be a stereo camera including a plurality of imaging devices, or may be imaging devices having pixels for phase difference detection.

For example, on the basis of distance information obtained from the imaging units 12101 to 12104, the microcomputer 12051 calculates the distances to the respective three-dimensional objects within the imaging ranges 12111 to 12114, and temporal changes in the distances (the velocities relative to the vehicle 12100). In this manner, the three-dimensional object that is the closest three-dimensional object on the traveling path of the vehicle 12100 and is traveling at a predetermined velocity (0 km/h or higher, for example) in substantially the same direction as the vehicle 12100 can be extracted as the vehicle running in front of the vehicle 12100. Further, the microcomputer 12051 can set beforehand an inter-vehicle distance to be maintained in front of the vehicle running in front of the vehicle 12100, and can perform automatic brake control (including follow-up stop control), automatic acceleration control (including follow-up start control), and the like. In this manner, it is possible to perform cooperative control to conduct automatic driving or the like to autonomously travel not depending on the operation of the driver.

For example, in accordance with the distance information obtained from the imaging units 12101 to 12104, the microcomputer 12051 can extract three-dimensional object data concerning three-dimensional objects under the categories of two-wheeled vehicles, regular vehicles, large vehicles, pedestrians, utility poles, and the like, and use the three-dimensional object data in automatically avoiding obstacles. For example, the microcomputer 12051 classifies the obstacles in the vicinity of the vehicle 12100 into obstacles visible to the driver of the vehicle 12100 and obstacles difficult to visually recognize. The microcomputer 12051 then determines collision risks indicating the risks of collision with the respective obstacles. If a collision risk is equal to or higher than a set value, and there is a possibility of collision, the microcomputer 12051 can output a warning to the driver via the audio speaker 12061 and the display unit 12062, or can perform driving support for avoiding collision by performing forced deceleration or avoiding steering via the drive system control unit 12010.

At least one of the imaging units 12101 to 12104 may be an infrared camera that detects infrared rays. For example, the microcomputer 12051 can recognize a pedestrian by determining whether or not a pedestrian exists in images captured by the imaging units 12101 to 12104. Such pedestrian recognition is carried out through a process of extracting feature points from the images captured by the imaging units 12101 to 12104 serving as infrared cameras, and a process of performing a pattern matching on the series of feature points indicating the outlines of objects and determining whether or not there is a pedestrian, for example. If the microcomputer 12051 determines that a pedestrian exists in the images captured by the imaging units 12101 to 12104, and recognizes a pedestrian, the sound/image output unit 12052 controls the display unit 12062 to display a rectangular contour line for emphasizing the recognized pedestrian in a superimposed manner. Further, the sound/image output unit 12052 may also control the display unit 12062 to display an icon or the like indicating the pedestrian at a desired position.

An example of a vehicle control system to which the technology (the present technology) according to the present disclosure may be applied has been described above. The technology according to the present disclosure can be applied to the imaging units 12031 and the like among the components described above, for example. Specifically, a solid-state imaging device of the present technology can be applied to the imaging units 12031. As the technique according to the present disclosure is applied to the imaging units 12031, it is possible to improve the quality and the like of the imaging units 12031.

Note that the present technology is not limited to the embodiments, examples of use, and example applications described above, and various modifications can be made to them without departing from the scope of the present technology.

Further, the advantageous effects described in this specification are merely examples, and the advantageous effects of the present technology are not limited to them and may include other effects.

Note that the present technology may also be embodied in the configurations described below.

[1]

A solid-state imaging device including a plurality of pixels arranged one- or two-dimensionally, in which each pixel includes at least a light receiving unit, and the light receiving unit included in at least some of the plurality of pixels have circularly polarized dichroism.

[2]

The solid-state imaging device according to [1], in which the light receiving unit of each of the pixels includes a filter unit, the filter unit includes at least an optical filter, and the optical filter included in the at least one of the pixels contains a material having circularly polarized dichroism.

[3]

The solid-state imaging device according to [2], in which the light receiving unit of each of the pixels includes one photoelectric conversion unit, and the filter unit is disposed on the photoelectric conversion unit.

[4]

The solid-state imaging device according to [2], in which the light receiving unit of each of the pixels includes a plurality of photoelectric conversion elements, the plurality of photoelectric conversion elements is stacked in a vertical direction, and the filter unit is disposed between the plurality of photoelectric conversion elements.

[5]

The solid-state imaging device according to any one of [2] to [4], in which the filter unit further includes a color filter, and the color filter and the optical filter are stacked.

[6]

The solid-state imaging device according to [5], in which colors of the color filters of the respective pixels are arranged so as to form a Bayer array in which each adjacent pixel has a different color, and the optical filters have different sensitivities to circularly polarized light between adjacent sets of repetitive units in the Bayer array.

[7]

The solid-state imaging device according to [5], in which colors of the color filters of the respective pixels are arranged so as to form a Bayer array in which each adjacent set of 2×2 pixels has a different color, and the optical filters have different sensitivities to circularly polarized light between adjacent sets of repetitive units in the Bayer array.

[8]

The solid-state imaging device according to [5], in which colors of the color filters of the respective pixels are arranged so as to form a Bayer array in which each adjacent pixel has a different color, and the optical filter in at least one of the pixels forming a set of repetitive units in the Bayer array has a different sensitivity to circularly polarized light from the other pixels forming the set of repetitive units.

[9]

The solid-state imaging device according to [5], in which colors of the color filters of the respective pixels are arranged so as to form a Bayer array in which each adjacent sets of 2×2 pixels has a different color, and the optical filter in at least one of the pixels forming a set of repetitive units in the Bayer array has a different sensitivity to circularly polarized light from the other pixels forming the set of repetitive units.

[10]

The solid-state imaging device according to [1], in which the light receiving unit of each of the pixels includes a filter unit, the filter unit includes at least a color filter, and the color filter included in the at least one of the pixels contains a material having circularly polarized dichroism.

[11]

The solid-state imaging device according to [10], in which colors of the color filters of the respective pixels are arranged so as to form a Bayer array in which each adjacent pixel has a different color, and the color filters have different sensitivities to circularly polarized light between adjacent sets of repetitive units in the Bayer array.

[12]

The solid-state imaging device according to [10], in which colors of the color filters of the respective pixels are arranged so as to form a Bayer array in which each adjacent sets of 2×2 pixels has a different color, and the color filters have different sensitivities to circularly polarized light between adjacent sets of repetitive units in the Bayer array.

[13]

The solid-state imaging device according to [10], in which colors of the color filters of the respective pixels are arranged so as to form a Bayer array in which each adjacent pixel has a different color, and the color filter in at least one of the pixels forming a set of repetitive units in the Bayer array has a different sensitivity to circularly polarized light from the other pixels forming the set of repetitive units.

[14]

The solid-state imaging device according to [10], in which colors of the color filters of the respective pixels are arranged so as to form a Bayer array in which each adjacent sets of 2×2 pixels has a different color, and the color filter in at least one of the pixels forming a set of repetitive units in the Bayer array has a different sensitivity to circularly polarized light from the other pixels forming the set of repetitive units.

[15]

The solid-state imaging device according to [1], in which the light receiving unit of each of the pixels includes one or more photoelectric conversion units, at least one photoelectric conversion unit of the one or more photoelectric conversion units includes an organic photoelectric conversion element, the organic photoelectric conversion element includes a pair of electrodes and a photoelectric conversion layer provided between the electrodes, and the photoelectric conversion layer of the organic photoelectric conversion element included in the at least one of the pixels contains a material having circularly polarized dichroism.

[16]

The solid-state imaging device according to [15], in which, of the one or more photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

[17]

The solid-state imaging device according to [15], in which the light receiving unit of each of the pixels includes: a first photoelectric conversion unit that photoelectrically converts light of a first color component; a second photoelectric conversion unit that photoelectrically converts light of a second color component; and a third photoelectric conversion unit that photoelectrically converts light of a third color component, one or more of the first, second, and third photoelectric conversion units each include an organic photoelectric conversion element, and the photoelectric conversion layer of the organic photoelectric conversion element included in the at least one of the pixels contains a material having circularly polarized dichroism.

[18]

The solid-state imaging device according to [17], in which, of the first, second, and third photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

[19]

The solid-state imaging device according to [15], in which the light receiving unit of each of the pixels includes, in this order: a first photoelectric conversion unit that photoelectrically converts light of a first color component; a filter unit; and a second photoelectric conversion unit that photoelectrically converts light of a second color component that has passed through the filter unit, one or more of the first and second photoelectric conversion units each include an organic photoelectric conversion element, and the photoelectric conversion layer of the organic photoelectric conversion element included in the at least one of the pixels contains a material having circularly polarized dichroism.

[20]

The solid-state imaging device according to [19], in which, of the first and second photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

[21]

The solid-state imaging device according to [1], in which the light receiving unit of each of the pixels includes a filter unit and a photoelectric conversion unit disposed in this order, the photoelectric conversion unit includes at least one panchromatic photosensitive organic photoelectric conversion film, and the panchromatic photosensitive organic photoelectric conversion film included in the at least one of the pixels contains a material having circularly polarized dichroism.

[22]

An imaging apparatus including at least: the solid-state imaging device according to any one of [1] to [21]; and a signal processing unit that generates an image capturing only specific circularly polarized light, on the basis of a signal obtained from the at least one of the pixels of the solid-state imaging device.

[23]

The imaging apparatus according to [22], in which the signal processing unit further generates an image not depending on a type of circularly polarized light, on the basis of a signal obtained from a pixel other than the at least one of the pixels.

[24]

The imaging apparatus according to [22], in which the signal processing unit interpolates information in each pixel, on the basis of information between adjacent pixels.

### REFERENCE SIGNS LIST

1 Imaging apparatus
10 Solid-state imaging device
20 Pixel
201 Light receiving unit
202 Wiring layer
30 On-chip lens
40 Optical filter
401 Optical filter
402 Color filter
41 Semiconductor substrate
42 Photodiode
43 Organic photoelectric conversion element
44 n-type region
45 Wiring line
46 Panchromatic photosensitive organic photoelectric conversion film

1. A solid-state imaging device comprising a plurality of pixels arranged one- or two-dimensionally, wherein each pixel includes at least a light receiving unit, and the light receiving unit included in at least one of the pixels has circularly polarized dichroism.

2. The solid-state imaging device according to claim 1, wherein the light receiving unit of each of the pixels includes a filter unit, the filter unit includes at least an optical filter, and the optical filter included in the at least one of the pixels contains a material having circularly polarized dichroism.

3. The solid-state imaging device according to claim 2, wherein the light receiving unit of each of the pixels includes one photoelectric conversion unit, and the filter unit is disposed on the photoelectric conversion unit.

4. The solid-state imaging device according to claim 2, wherein the light receiving unit of each of the pixels includes a plurality of photoelectric conversion units, the plurality of photoelectric conversion units is stacked in a vertical direction, and the filter unit is disposed between the plurality of photoelectric conversion units.

5. The solid-state imaging device according to claim 2, wherein the filter unit further includes a color filter, and the color filter and the optical filter are stacked.

6. The solid-state imaging device according to claim 5, wherein colors of the color filters of the respective pixels are arranged so as to form a Bayer array in which each adjacent pixel has a different color, and the optical filters have different sensitivities to circularly polarized light between adjacent sets of repetitive units in the Bayer array.

7. The solid-state imaging device according to claim 5, wherein colors of the color filters of the respective pixels are arranged so as to form a Bayer array in which each adjacent pixel has a different color, and the optical filter in at least one of the pixels forming a set of repetitive units in the Bayer array has a different sensitivity to circularly polarized light from the other pixels forming the set of repetitive units.

8. The solid-state imaging device according to claim 1, wherein the light receiving unit of each of the pixels includes a filter unit, the filter unit includes at least a color filter, and the color filter included in the at least one of the pixels contains a material having circularly polarized dichroism.

9. The solid-state imaging device according to claim 8, wherein colors of the color filters of the respective pixels are arranged so as to form a Bayer array in which each adjacent pixel has a different color, and the color filters have different sensitivities to circularly polarized light between adjacent sets of repetitive units in the Bayer array.

10. The solid-state imaging device according to claim 8, wherein colors of the color filters of the respective pixels are arranged so as to form a Bayer array in which each adjacent pixel has a different color, and the color filter in at least one of the pixels forming a set of repetitive units in the Bayer array has a different sensitivity to circularly polarized light from the other pixels forming the set of repetitive units.

11. The solid-state imaging device according to claim 1, wherein the light receiving unit of each of the pixels includes one or more photoelectric conversion units, at least one photoelectric conversion unit of the one or more photoelectric conversion units includes an organic photoelectric conversion element, the organic photoelectric conversion element includes a pair of electrodes and a photoelectric conversion layer provided between the electrodes, and the photoelectric conversion layer of the organic photoelectric conversion element included in the at least one of the pixels contains a material having circularly polarized dichroism.

12. The solid-state imaging device according to claim 11, wherein, of the one or more photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

13. The solid-state imaging device according to claim 11, wherein the light receiving unit of each of the pixels includes: a first photoelectric conversion unit that photoelectrically converts light of a first color component; a second photoelectric conversion unit that photoelectrically converts light of a second color component; and a third photoelectric conversion unit that photoelectrically converts light of a third color component, one or more of the first, second, and third photoelectric conversion units each include an organic photoelectric conversion element, and the photoelectric conversion layer of the organic photoelectric conversion element included in the at least one of the pixels contains a material having circularly polarized dichroism.

14. The solid-state imaging device according to claim 13, wherein, of the first, second, and third photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

15. The solid-state imaging device according to claim 11, wherein the light receiving unit of each of the pixels includes, in this order: a first photoelectric conversion unit that photoelectrically converts light of a first color component; a filter unit; and a second photoelectric conversion unit that photoelectrically converts light of a second color component that has passed through the filter unit, one or more of the first and second photoelectric conversion units each include an organic photoelectric conversion element, and the photoelectric conversion layer of the organic photoelectric conversion element included in the at least one of the pixels contains a material having circularly polarized dichroism.

16. The solid-state imaging device according to claim 15, wherein, of the first and second photoelectric conversion units in the at least one of the pixels, at least one photoelectric conversion unit includes at least a first organic photoelectric conversion element and a second organic photoelectric conversion element, and the first organic photoelectric conversion element and the second organic photoelectric conversion element have different sensitivities to circularly polarized light.

17. The solid-state imaging device according to claim 1, wherein the light receiving unit of each of the pixels includes a filter unit and a photoelectric conversion unit disposed in this order, the photoelectric conversion unit includes at least one panchromatic photosensitive organic photoelectric conversion film, and the panchromatic photosensitive organic photoelectric conversion film included in the at least one of the pixels contains a material having circularly polarized dichroism.

18. An imaging apparatus comprising at least: the solid-state imaging device according to claim 1; and a signal processing unit that generates an image capturing only specific circularly polarized light, on a basis of a signal obtained from the at least one of the pixels of the solid-state imaging device.

19. The imaging apparatus according to claim 18, wherein the signal processing unit further generates an image not depending on a type of circularly polarized light, on a basis of a signal obtained from a pixel other than the at least one of the pixels.

20. The imaging apparatus according to claim 18, wherein the signal processing unit interpolates information in each pixel, on a basis of information between adjacent pixels.
